(19) United States
(12) Patent Application Publication
(10) Pub. No.: US 2025/0291616 A1
(43) Pub. Date: Sep. 18, 2025

(54) ARCHITECTURE OF A SCIENTIFIC VISUALIZATION SYSTEM

(71) Applicant: Luminary Cloud, Inc., San Mateo, CA (US)

(72) Inventors: Matthew Larsen, San Lorenzo, CA (US); Duong Hoang, San Mateo, CA (US); Sudhanshu Sane, Eugene, OR (US); William Usher, Lake Forest, CA (US)

(21) Appl. No.: 18/923,205

(22) Filed: Oct. 22, 2024

Related U.S. Application Data
(60) Provisional application No. 63/564,062, filed on Mar. 12, 2024.

(51) Int. Cl. G06F 9/455; G06F 3/14

(52) U.S. Cl. CPC G06F 9/455; G06F 3/14

(57) ABSTRACT

A scientific visualization system includes a plurality of components configured to provide visualization of filtered results of physical simulation software code (e.g., simulations) executing on virtualized resources (e.g., compute, memory and storage resources) of a cloud-based, virtual data center (server) computing environment. The scientific visualization system is further configured to render visualization images of the filtered simulation results for subsequent display at a client computer (client), or in part visualized at the client, such as a user interface browser of the client. Filtering of the simulation results and rendering of the images may be performed using visualization analysis software executing on the server of the computing environment, although rendering of the visualization images may alternatively be performed either on the server (server-side rendering) or client (client-side rendering).

### CROSS-REFERENCE TO RELATED APPLICATION

The present application claims the benefit of U.S. Provisional Patent Application Ser. No. 63/564,062, which was filed on Mar. 12, 2024, by Matthew Larsen for SCIENTIFIC VISUALIZATION SYSTEM, which is hereby incorporated by reference.

### BACKGROUND

### Technical Field

The present disclosure relates to virtualized computing environments and, more specifically, to a scientific (and engineering) visualization system configured to provide visualization of results of physical simulation software code executing on a cloud-based, virtualized computing environment.

### Background Information

Scientific visualization transforms large datasets of applications into understandable and useful graphical and image-based representations of information (visualizations) on a client (e.g., end-user device and application) involving an engineering project. The applications may include physical simulation software for computer aided engineering (CAE) processed on computing resources of a computing environment. These large datasets may be conveyed as various types of visualizations such as three dimensional (3D) views of objects, 3D slice planes, and 2D plots of quantities (e.g., pressure) along the surfaces of objects, for example rockets or golf balls, for single or multiple (ensemble) simulations.

Typically, the computing environment is a high-performance computing (HPC) visualization deployment of super-computers having a homogeneous set of known (predefined) resources adapted to execute conventional visualization library software packages for rendering on a client. In contrast, a cloud-based, virtual data center (VDC) of a virtualized computing environment may employ virtualized resources that are more diverse (heterogeneous) and dynamically changing, and thus provide a unique set of constraints that are not encountered by most HPC deployments. The cloud-based VDC may have a varying amount of different compute resources and memory/storage resources, as well as the networking resources whose links or interconnections (e.g., between clients and the VDC, as well as between resources of the VDC) may vary from low bandwidth and high latency (weak) to high bandwidth and low latency (strong) as well as a wide variety of client resources (memory and computation) such that allocation and scheduling of such resources is difficult and challenging to meet user experience expectations, e.g., sufficiently low latency and bandwidth, based on capability. Accordingly, there is a need for an efficient and flexible system configured to operate optimally in such a heterogeneous environment.

### BRIEF DESCRIPTION OF THE DRA WINGS

The above and further advantages of the embodiments herein may be better understood by referring to the following description in conjunction with the accompanying drawings in which like reference numerals indicate identically or functionally similar elements, of which:

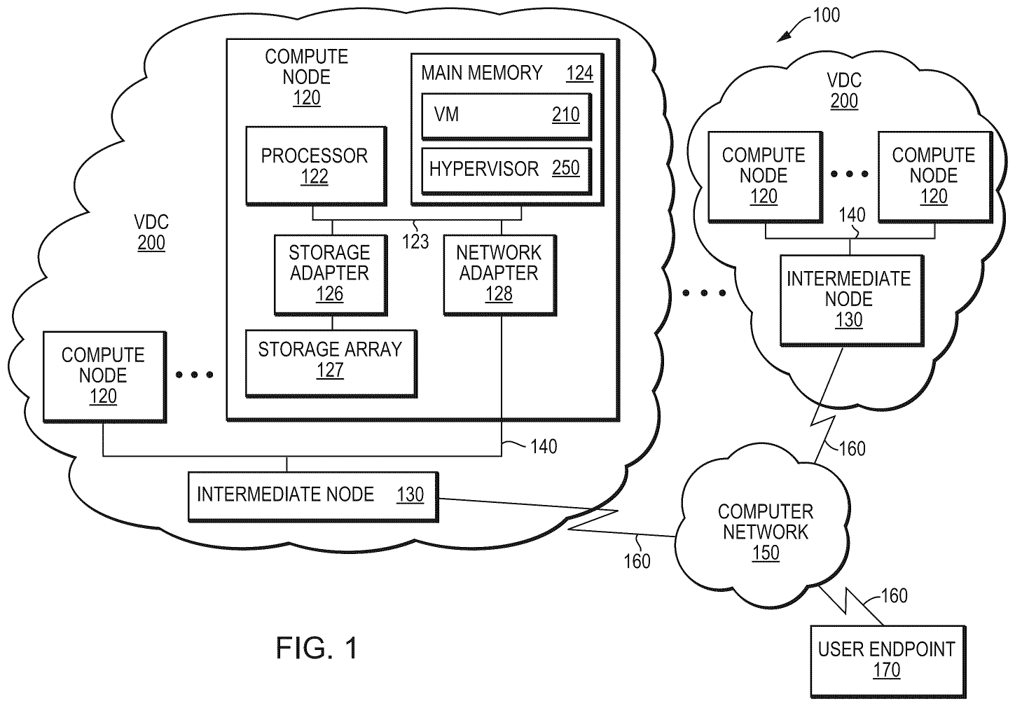

FIG. 1 is a schematic block diagram of a virtualized computing environment;

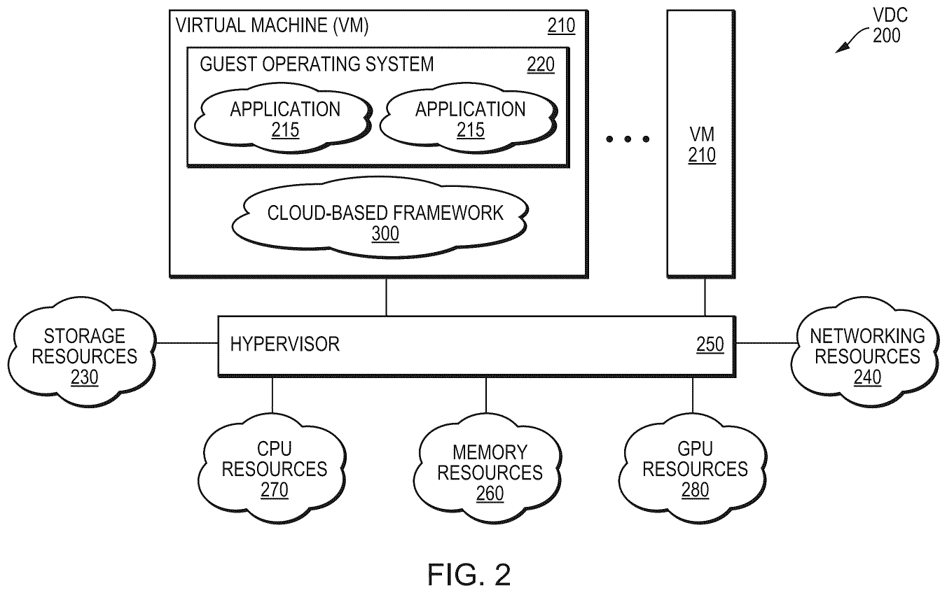

FIG. 2 is a schematic block diagram of a virtual data center;

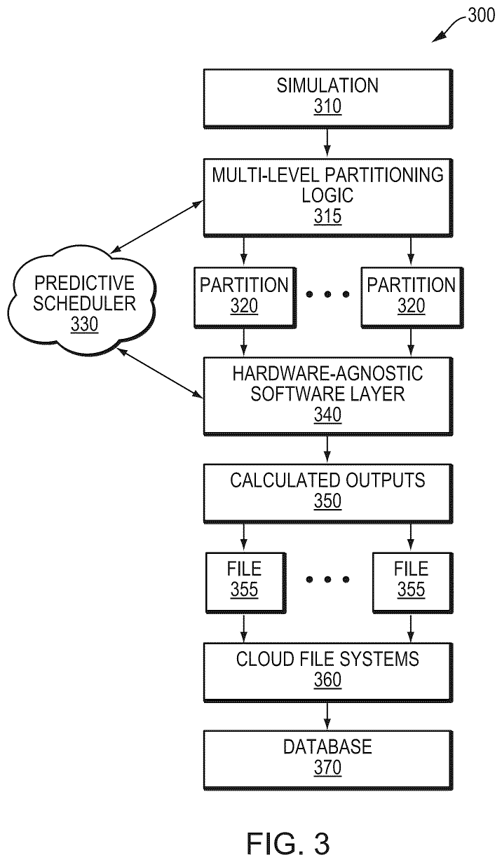

FIG. 3 is a schematic block diagram of a cloud-based framework;

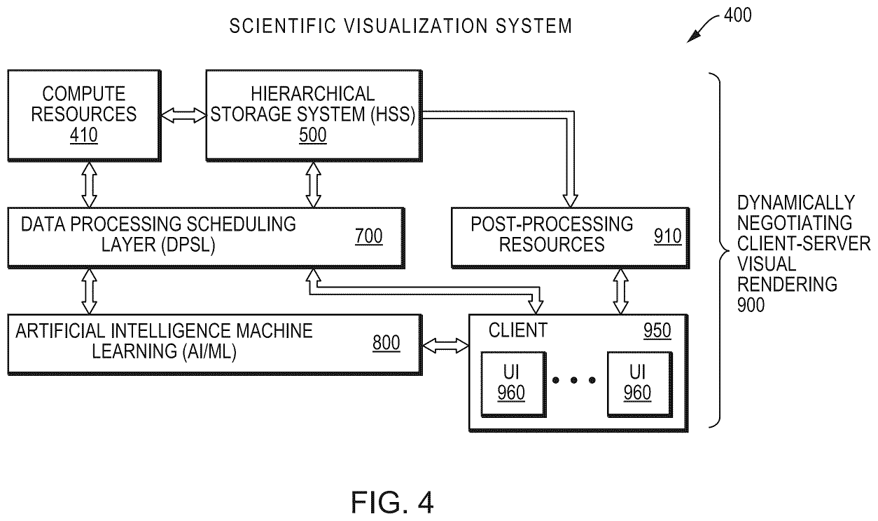

FIG. 4 is a schematic block diagram of a cloud-based scientific visualization system;

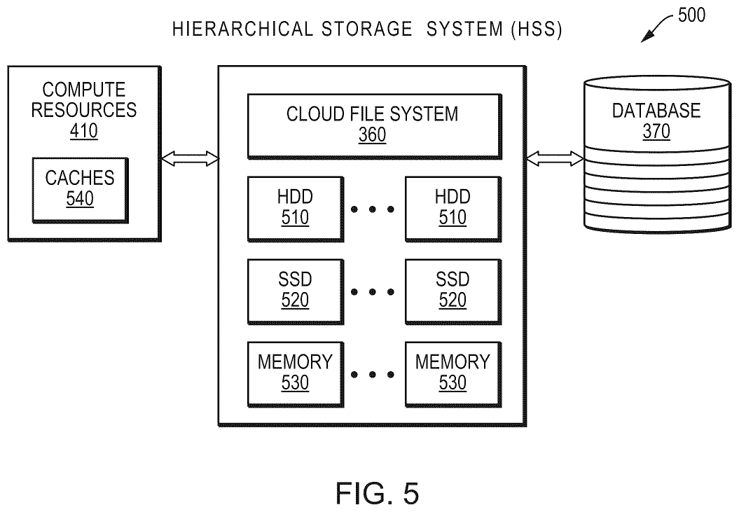

FIG. 5 is a schematic block diagram of a hierarchical storage system;

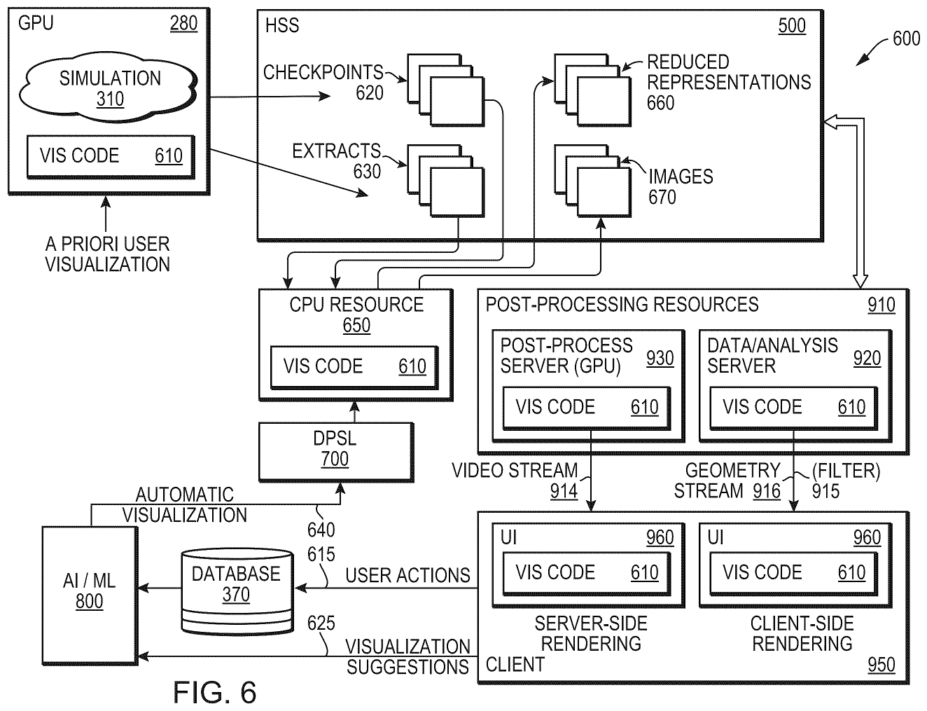

FIG. 6 is a schematic block diagram of an exemplary embodiment of the scientific visualization system;

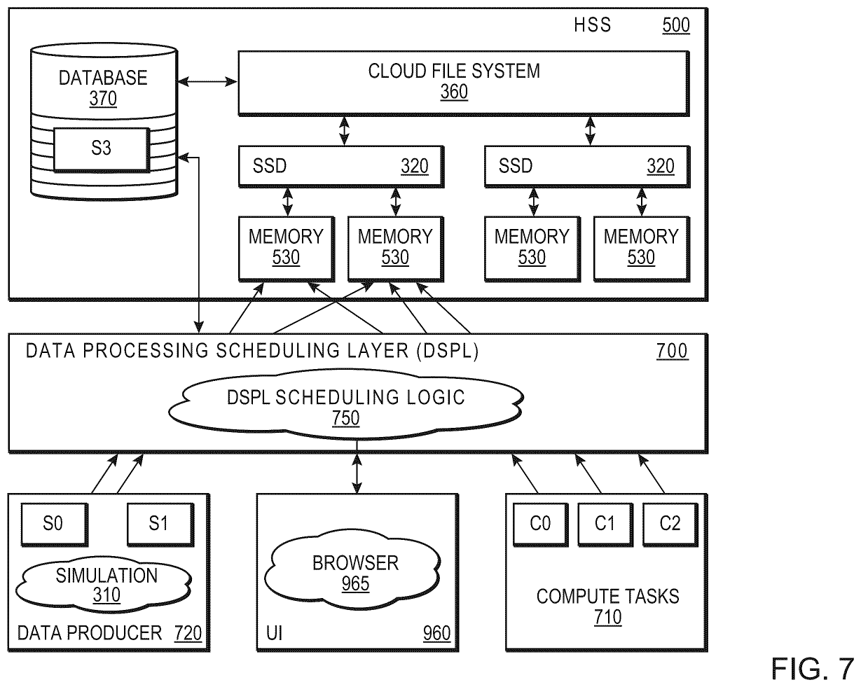

FIG. 7 is a schematic block diagram of a data processing scheduling layer component of the scientific visualization system;

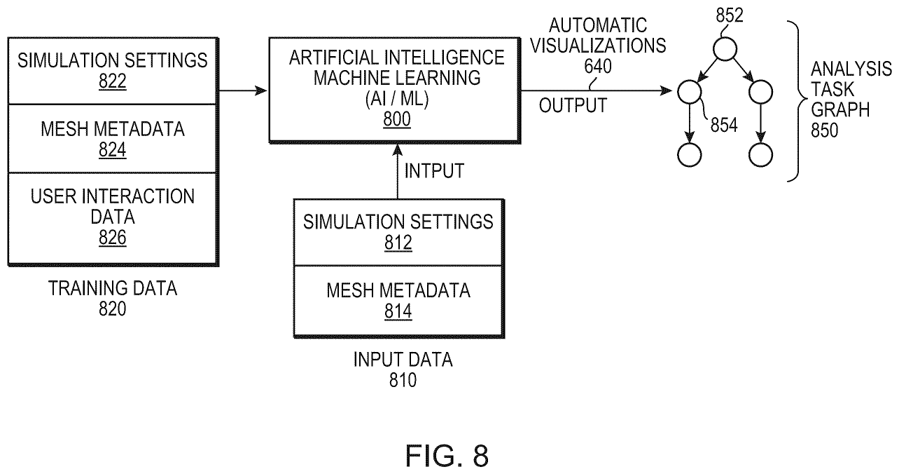

FIG. 8 is a schematic block diagram of an artificial intelligence/machine learning component of the scientific visualization system;

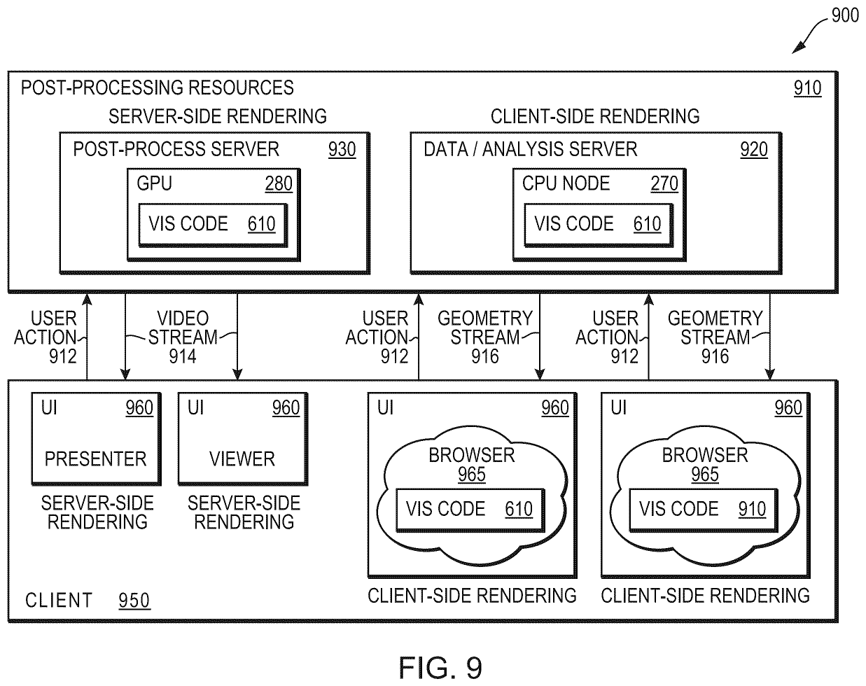

FIG. 9 is a schematic block diagram of a dynamically negotiating client-server visual rendering component of the scientific visualization system;

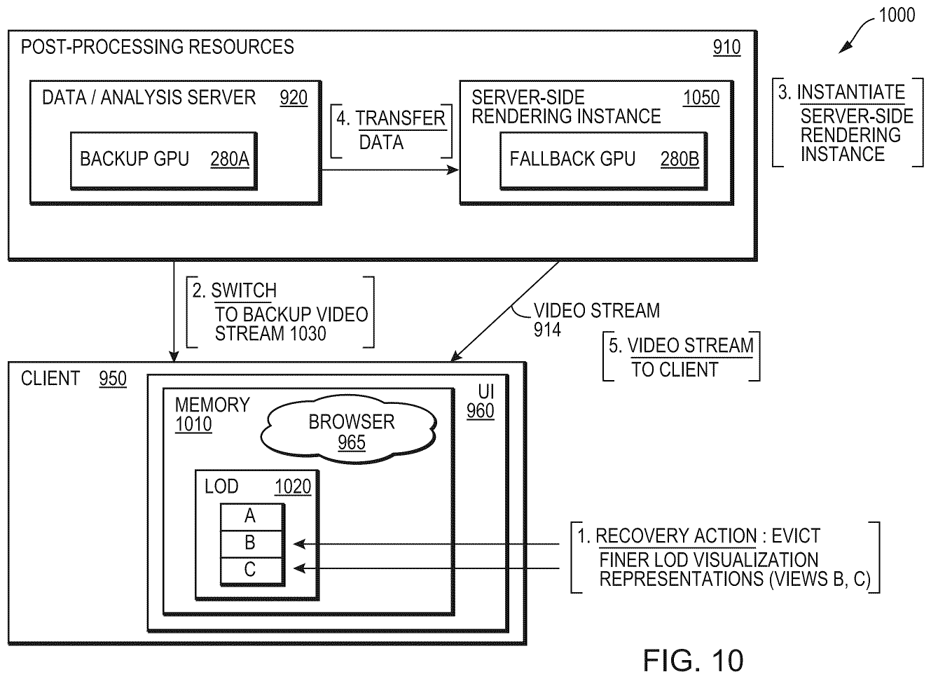

FIG. 10 is a schematic block diagram illustrating a client-side rendering fallback workflow of the scientific visualization system;

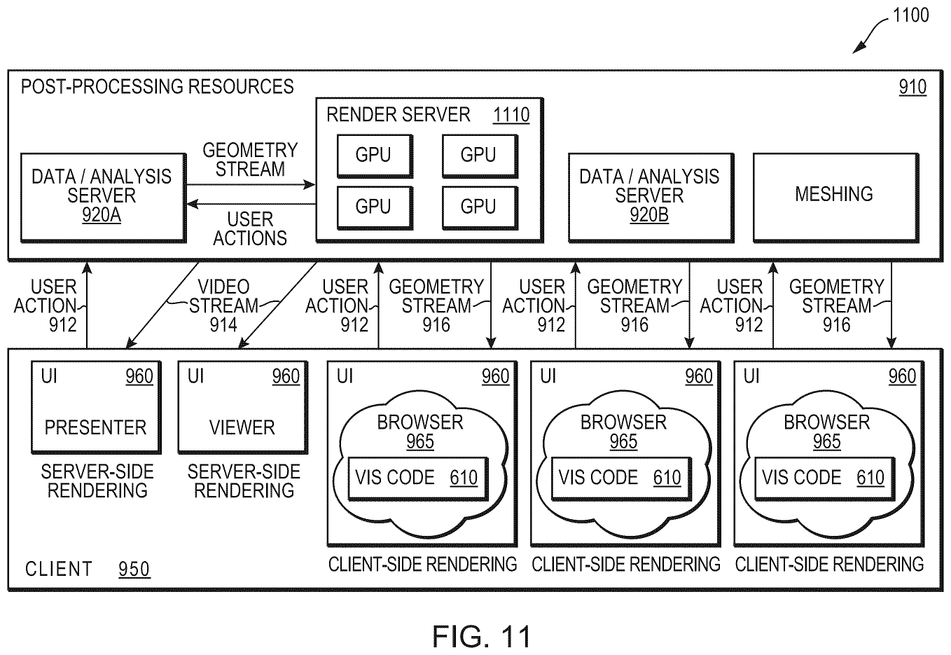

FIG. 11 is a schematic block diagram of client-side rendering fallback of the scientific visualization system;

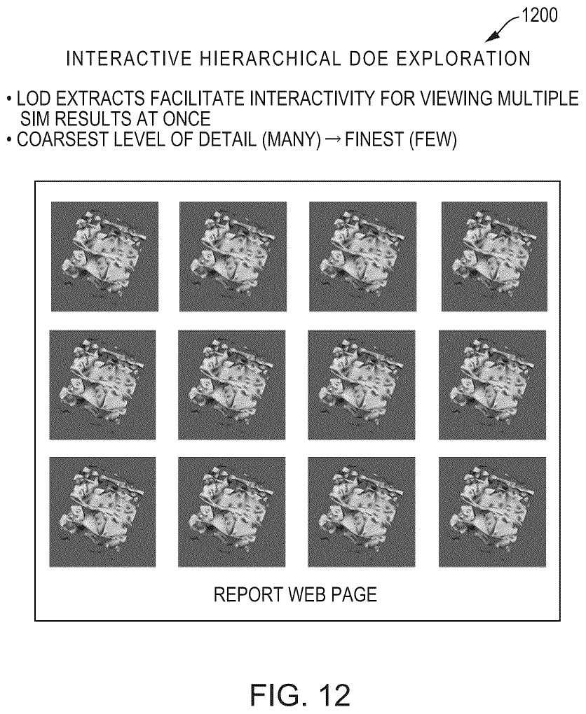

FIG. 12 is a diagram illustrating an interactive hierarchical design of experiments exploration feature of the scientific visualization system; and

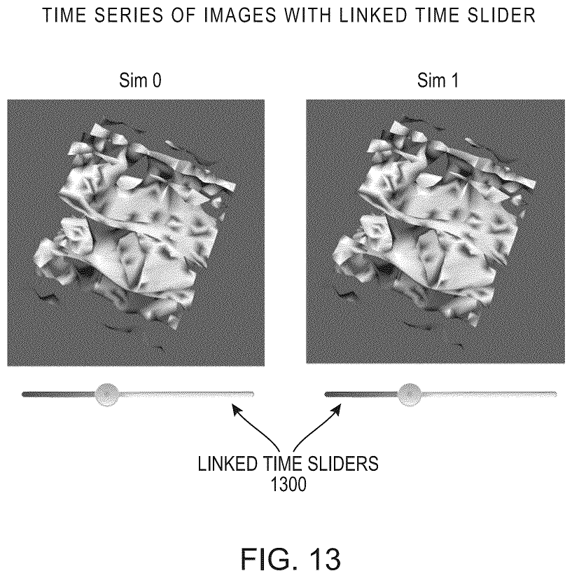

FIG. 13 is a diagram of a linked time slider of the scientific visualization system.

### OVERVIEW

The embodiments described herein are directed to a scientific visualization system including a plurality of components configured to provide visualization of filtered (extracted and/or reduced) results of physical simulation software code (e.g., simulations) executing on virtualized resources (e.g., compute, memory, and storage resources) of a cloud-based, virtual data center (server) computing environment. The scientific visualization system is further configured to render (create) visualization images of the filtered simulation results for subsequent display at an end-user computer/device and application (client), or in part visualized at the client, such as a browser application user interface of the client. Filtering of the simulation results and rendering of the images may be performed using visualization analysis software (e.g., visualization analysis code or, more generally, visualization code) executing on the server of the computing environment with the rendered images sent to the client, although the rendering may be performed either on the server (server-side rendering) or client (client-side rendering). The virtualized compute resources of the virtual data center (VDC) include general-purpose hardware processor resources, such as central processing unit (CPU) nodes as well as specialized computational (hardware) accelerator resources, such as graphics processing units (GPUs). The components of the scientific visualization system include an artificial intelligence/machine learning (AI/ML or, more generally, ML) component, a data processing scheduling layer (DPSL) component, and a dynamically negotiating client-server visual rendering component that each interact with a hierarchical storage system (HSS) configured to store and retrieve the results (e.g., datasets) of the simulations that are processed on/by the virtualized resources of the server (VDC).

In an embodiment, the scientific visualization system supports multiple execution environments including multi-physics simulations, transient simulations (i.e., simulations that model evolution of physical phenomena over time) and steady-state simulations (i.e., simulations that converge at a single point in time) with substantially large datasets. Support for the transient and steady-state execution environments requires flexibility to handle constraints of a cloud-based computing environment having diverse (heterogeneous) and dynamically changing virtualized resource requirements, e.g., memory, speed, hardware, and rendering constraints. To that end, a “portable performance” feature of the system allows for execution on different types of computational resources by providing a hardware independent abstraction layer (software library) application programming interface (API) that enables compiling of the visualization code (e.g., filters) for execution across the multiple (different types) compute resources (CPU or GPU) of the VDC, i.e., portable performance provides a “single code base, multiple use case” solution via the abstraction layer library. Illustratively, the visualization code is written in a manner that is flexible enough to meet resource constraints (available compute/memory) within the dynamically changing, resource-bounded (constrained) environment according to various strategies, e.g., use as little memory as possible or execute as fast as possible. The portable performance (“portability”) feature may further extend to visualization rendering such that same visualization rendering code may be employed for a client lacking processing resource capabilities (e.g., a “thin client” needing server-side rendering) or a client having sufficient processing capabilities (e.g., a “thick client” capable of client-side rendering). The portability feature of the system may thus be embodied as a plurality of targeted abstraction layer libraries (i.e., hardware specific implementations of the abstraction layer libraries) that enables compiling and execution of visualization code on either the server or client so that placement of visual rendering execution may be negotiated according to client capabilities.

In an embodiment, the components of the scientific visualization system cooperate to perform in-situ or in-transit simulation visualization, along with automatic analysis, where visualization code may be executed (i) on a compute resource sharing memory and computation with a portion of the simulation, (ii) on a separate compute resource (i.e., not sharing execution with the simulation), or (iii) as a post-process (after completion of the simulation). Moreover, the scientific visualization system may be configured to consume, synthesize, and organize (i.e., make sense of) large amounts of datasets as an ensemble of simulation results by, e.g., creating visualizations that enable interactive viewing and querying based on user-controllable filters. Notably, the user-controlled filters help users manage the volume of simulation results (i.e., size of datasets) through steering the simulation to decimate (i.e., reduce) the datasets to areas of interest for visual comparison and navigate through the reduced (i.e., filtered, decimated) datasets (extracts) within a single user-interactive platform controlled from the client. This latter aspect of the system includes both quantitative filtering (e.g., parameter filter expressions), as well as qualitative visualization for ensemble analysis, such as automatically increasing detail as the viewed simulation results are narrowed or reduced.

In an embodiment, the visualization components of the scientific visualization system cooperate to place or move processing (e.g., calculations) of the visualization code (e.g., manifested as compute tasks) to locations of the compute resources in proximity where data (i.e., intermediate simulation results relevant for visualization) resides, e.g., in GPU memory for execution on a GPU alongside simulations (including mesh generation), in CPU memory on a CPU node, or on a post-processing resource (allocated GPU or CPU). Illustratively, the DPSL component maintains location information for the compute tasks so that tasks operating on or using the same information may be placed in proximity for high bandwidth, low latency access to that information (e.g., shared access to data in a memory of a GPU). For example, the GPU may execute simulations along with visualization code to generate checkpoints (full simulation snapshots persisted at points in time) and extracts of predefined visualizations (e.g., slices and contours into portions of the simulation dataset that are essentially sub-sets of the checkpoints) for storage on the HSS. A client (user) may provide user actions, e.g., one or more visualization parameters and user defined visualizations, embodied as compute tasks directed to the simulations from a user interface (UI) to the ML component, which may automatically generate anticipated (i.e., user expected based on past behavior) visualizations that are then scheduled for processing by a compute (e.g., CPU) resource via the DPSL component. The CPU resource processes the automatic visualization in connection with the checkpoints and extracts to generate reduced representations (reduced checkpoints) and images that may be provided to post-processing resources for interactive exploration by the client (user).

### DESCRIPTION

FIG. 1 is a schematic block diagram of a virtualized computing environment 100 that may be advantageously used with a cloud-based framework disclosed herein. The virtualized computing environment includes one or more virtual data centers (VDCs 200) configured to provide virtualization that transforms physical hardware of the environment into virtual resources, as well as cloud computing that enables on-demand access to the virtualized resources, e.g., over a computer network. In an illustrative embodiment, the architecture of the cloud-based framework extends the virtualization and cloud-computing capabilities of the VDCs 200 to provide improved execution of workloads, such as computer aided engineering (CAE) physical simulation software (e.g., physics solver code), as a cloud-based service offering, such as Software as a Service (SaaS), to users in a highly available, reliable, and cost-effective manner.

In an embodiment, the virtualized computing environment 100 includes one or more compute nodes 120 and intermediate nodes 130 illustratively embodied as one or more VDCs 200 interconnected by a computer network 150. The VDCs 200 may be cloud service providers (CSPs) deployed as private clouds or public clouds, such as deployments from Amazon Web Services (AWS), Google Compute Engine (GCE) of the Google Compute Project (GCP) ecosystem, Microsoft Azure, or VMWare. Each VDC 200 may be configured to provide virtualized resources, such as virtual storage, networking, memory, and/or processor resources that are accessible over the computer network 150, such as the Internet, to users at one or more user endpoints 170. Each compute node 120 is illustratively embodied as a computer system having one or more processors 122, a main memory 124, one or more storage adapters 126, and one or more network adapters 128 coupled by a network segment 123, such as a system interconnect. The storage adapter 126 may be configured to access information stored on magnetic/solid state storage devices, e.g., hard disk drives (HDDs), solid state drives (SDDs) or other similar media, of storage array 127. To that end, the storage adapter 126 may include input/output (I/O) interface circuitry that couples to the storage devices over an I/O interconnect arrangement, such as a conventional peripheral component interconnect (PCI), serial ATA (SATA), or non-volatile memory express (NVMe) topology.

The network adapter 128 connects the compute node 120 to other compute nodes 120 of the VDC 200 over local network segments 140 illustratively embodied as shared local area networks (LANs) or virtual LANs (VLANs). The network adapter 128 may thus be embodied as a network interface card (NIC) having the mechanical, electrical and signaling circuitry needed to connect the compute node 120 to the local network segments 140. The intermediate node 130 may be embodied as a network switch, router, or virtual private network (VPN) gateway that interconnects the LAN/VLAN local segments with remote network segments 160 illustratively embodied as point-to-point links, wide area networks (WANs), and/or VPNs implemented over a public network (such as the Internet). The VDC may utilize many different, heterogeneous network segments 123, 140, 160 for intra-node, inter-node, and inter-VDC communication, respectively, wherein the heterogeneous networks are diverse in characteristics such as bandwidth and latency. Communication over the network segments 140, 160 may be affected by exchanging discrete frames or packets of data according to pre-defined protocols, such as the Transmission Control Protocol/Internet Protocol (TCP/IP) and the OpenID Connect (OIDC) protocol, although other protocols, such as the User Datagram Protocol (UDP), the NVIDIA Collective Communications Library (NCCL), Infiniband, or the HyperText Transfer Protocol Secure (HTTPS) may also be advantageously employed.

The main memory 124 includes a plurality of memory locations addressable by the processor 122 and/or adapters for storing software code (e.g., processes and/or services) and data structures associated with the embodiments described herein. The processor and adapters may, in turn, include processing elements and/or circuitry configured to execute the software code, such as a virtual machine (VM) 210 and a hypervisor 250, and manipulate the data structures. The processors 122 may include general-purpose hardware processor resources, such as central processing units (CPUs) as well as specialized hardware accelerator resources, such as tensor processing units (TPUs) or, in an illustrative embodiment, graphics processing units (GPUs).

It will be apparent to those skilled in the art that other types of processing elements and memory, including various computer-readable media, may be used to store and execute program instructions pertaining to the embodiments described herein. Also, while the embodiments herein are described in terms of software code, processes, and computer, e.g., application, programs stored in memory, alternative embodiments also include the code, processes and programs being embodied as logic, components, and/or modules consisting of hardware, software, firmware, or combinations thereof.

FIG. 2 is a schematic block diagram of a virtual data center (VDC) 200 including one or more virtual machines (VMs) 210. Each VM 210 is managed by a hardware abstraction layer, e.g., a hypervisor 250, which is a virtualization platform configured to mask low-level hardware operations from one or more guest operating systems executing in the VM 210. In an embodiment, the hypervisor 250 is illustratively the Xen hypervisor, although other types of hypervisors, such as the Hyper-V hypervisor and/or VMware ESXI hypervisor, may be used in accordance with the embodiments described herein. A guest operating system (OS) 220 and applications 215, such as physical simulation software (e.g., physics solver code), may run in the VM 210 and may be configured to utilize hardware resources of the VDC 200 that are virtualized by the hypervisor 250. The guest OS 220 may be the Linux operating system, FreeBSD and similar operating systems; however, it should be noted that other types of guest OSs, such as the Microsoft Windows operating system, may be used in accordance with the embodiments described herein. The guest OS 220 and applications 215 may be managed, at least in part, by the cloud-based framework 300 executing in the VM 210 and configured to extend the virtualization and cloud-computing capabilities of VDC 200, including the utilization of virtualized resources.

As noted, the virtualized resources of the virtualized computing environment include storage, networking, memory, and/or processor resources. In an embodiment, the VDC 200 may organize the resources as pools of virtualized resources. For example, the VDC 200 may organize the virtualized resources as pools of virtualized storage (e.g., HDD and/or SSD) resources 230, networking (e.g., NIC) resources 240, memory (e.g., random access memory) resources 260, and processor resources, such as pools of general-purpose processing resources and specialized processing resources. The pool of general-purpose processing resources may be embodied as a pool of CPUs 270 and the pool of specialized processing resources may be embodied as accelerators, such as TPUs or, illustratively, a pool of GPUs 280. These pools of resources may be organized and distributed among the compute nodes 120 of the VDC 200.

The embodiments described herein are related to a cloud-based framework having an architecture configured to dynamically utilize the distributed pool of specialized processing resources (i.e., accelerators) to speed-up, as well as parallelize (further speed-up), processing (e.g., calculations) of physical simulation software (e.g., computational fluid dynamics/physics solver code or, more generally, simulations) partitioned across multiple accelerators (e.g., GPUs). FIG. 3 is a schematic block diagram of the cloud-based framework 300. An input data set (e.g., a mesh) of the physics solver code (simulation 310) may be partitioned, e.g., via multi-level partitioning logic 315 of the cloud-based framework 300, into simulation kernels having one or more partitions 320 (i.e., code groups) that are configured to run on the GPUs 280. A predictive scheduler 330 interacts with the multi-level partitioning logic 320 to locate, reserve, dynamically access, and thereafter release the GPUs needed for running the simulation kernels. The framework 300 is configured to efficiently use bandwidth/compute capacity of the GPUs 280 for simulation calculated outputs 350 asynchronously (via a hardware agnostic layer 340 implementing a hardware independent application programming interface) and in cooperation with CPUs 270 as needed and on user demand. The results from the simulation calculated outputs 350 are written as files 355 to one or more cloud file systems 360. The files may include substantial amounts of data, which may be indexed and organized as output datasets that are, in turn, persistently and asynchronously stored as a query-able database 370. An example of a cloud-based framework that may be advantageously used with the embodiments herein is described in co-pending and commonly assigned U.S. patent application Ser. No. 17/843,457 filed Jun. 17, 2022, and titled Cloud-Based Framework for Analysis Using Accelerators, which application is hereby incorporated by reference as though fully set forth herein.

The cloud-based framework 300 enables a multi-pronged approach that allows a user to analyze and visualize large datasets interactively using a scientific visualization system of the framework. If, prior to or during a simulation, the user specifies the data extraction/visualization desired, the framework (e.g., scientific visualization system) extracts the data required for such visualizations (vastly smaller than a full solution) and stores the data in a hierarchical data format (e.g., Hierarchical Data Format 5) for fast access/retrieval, resulting in improved interactivity and reduced dataset sizes. Illustratively, such an “in-situ” extraction of information may occur during the running (execution) of the simulation (e.g., on the same set of compute resources as the simulation or on a concurrent set of resources) and not after the simulation is completed. However, if the user does not specify a desired visualization prior to/during the running of a simulation, the system may store the entire output file and visualize whatever the user requests after the simulation has run. Notably, performance enhancements to the framework include improvements to I/O communication and visualization speed through parallelization of a visualization pipeline (e.g., embodied as a scientific visualization system) and creation of visualization extracts post-hoc (i.e., after the simulation has run).

Specifically, parallelization (and use of significant resources) of the scientific visualization system may be achieved through various methods such as (i) performing both visualization and rendering on GPU 280 (rather than visualization on CPU 270 and rendering on GPU); (ii) creating a storage hierarchy (e.g. Google storage), where files 355 are stored on pools of storage resources 230 (e.g., SSDs) to improve bandwidth and from where information in the files may be speculatively loaded into pools of (CPU or GPU) memory resources for visualization/rendering closer to where the information is consumed and/or likely to be used; and (iii) ensuring that the resources used for visualization and rendering can be tailored for low latency response (real-time engineering/visualization) leveraging the flexibility of the VDC 200. Moreover, users can create visualization and analysis templates (e.g., a domain-specific arrangement of slice planes, images, and plots) that can be applied to one or more simulation results for the purpose of comparison (i.e., a design exploration) or communication (i.e., easily sharing a curated set of results with other users).

In situations where the user does specify which extractions/visualizations are desired and (smaller) data files do not provide the necessary level of interactivity, additional embodiments may pursue other approaches to enhance analysis. For example, the analysis may be enhanced through pre-rendering of images or scalar images (i.e., images that contain scalar data, depth information, and/or lighting information that can be re-colored and composed in an interactive fashion). Pre-rendering in this context may be performed either (i) in-situ with extracted images being determined a priori or automatically based on, e.g., machine learning or (ii) by creating the images at a temporal resolution of full simulation snapshots persisted at points in time, e.g., checkpoints. Image data, by virtue of being rendered to a visual resolution, is substantially smaller than raw volume data and, thus, may be displayed interactively, e.g., as a movie, and the simulation viewed over time. The image data may be used to facilitate filtering of large amounts of time steps or compare the results of ensemble simulations far faster than interacting with large amounts of volumetric data.

### Scientific Visualization System

The embodiments described herein are directed to a scientific visualization system including a plurality of components configured to provide visualization of filtered (extracted and/or reduced) results of physical simulation software code (e.g., simulations) executing on virtualized resources (e.g., compute, memory, and storage resources) of a cloud-based, VDC (server) computing environment. The scientific visualization system is further configured to render (create) visualization images of the filtered simulation results for subsequent display at a client computer (client), or in part visualized at the client, such as a user interface browser of the client. Filtering of the simulation results and rendering of the images may be performed using visualization analysis software (e.g., visualization analysis code or, more generally, visualization code) executing on the server of the computing environment with the rendered images sent to the client, although the rendering may be performed either on the server (server-side rendering) or client (client-side rendering).

As noted, high-performance computing (HPC) visualization deployments typically include conventional visualization library software packages that may be compiled to execute on super-computers, where each super-computer has a homogeneous set of known (predefined) resources. In addition, conventional visualization tools are typically implemented as complete post-processors, e.g., desktop visualization applications (e.g., Paraview) that run on client computers, where users download and interact with simulation results (e.g., a simulation file). The scientific visualization system described herein allows the same interactivity natively (designed from ground-up) in the cloud-based VDC environment by, e.g., user-driven refinement on-demand to interactively generate and precisely display specific simulation areas of interest for the user. The visualization system can also be used to visualize geometry and meshes (and quantities derived from geometry and meshes) that can be quite large. However, the cloud based VDC has virtualized resources that are more diverse (heterogeneous) and dynamically changing, and thus provide a unique set of constraints that are not encountered by most HPC deployments. Moreover, visualization code execution is constrained to resources allocated by the cloud-based environment in order to implement metrics needed to provide a visualization service of the environment. For example, instead of a very fast interconnect for communication among the resources and a client, the scientific visualization system may have a standard interconnect provided by the cloud environment. Yet, the system must be flexible enough to perform operations efficiently despite those constraints.

FIG. 4 is a schematic block diagram of the cloud-based scientific visualization system 400 configured for interactive visualization of simulation results on a VDC computing environment. Components of the scientific visualization system 400 include an artificial intelligence/machine learning (AI/ML or, more generally, ML) component 800, a data processing scheduling layer (DPSL) component 700, and a dynamically negotiating client-server visual rendering component 900 (e.g., post-processing resources 910 and one or more clients 950) that each interact with a hierarchical storage system (HSS) 500 configured to store and retrieve the results (e.g., datasets) of the simulations that are processed on/by the virtualized compute resources 410 of the server (VDC). The (virtualized) compute resources 410 include general-purpose hardware processor resources, such as CPU resources (hereinafter CPU nodes 270) as well as specialized computational (hardware) accelerator resources, such as GPU resources (hereinafter GPUs 280).

In an embodiment, the scientific visualization system 400 is part of the larger cloud-based framework 300 executing on the VDC 200 and cooperates with the framework 300 to allocate (reserve and activate) a compute resource 410, e.g., a CPU node 270 or GPU 280, to execute the visualization code. The system may make algorithm trade-offs between processing speed and memory consumption depending on available resources. For example, typically, a GPU environment is memory-constrained, so if there is a choice for task memory consumption between a greater or lesser memory use, the system chooses a less consumptive memory approach. For a CPU environment that typically has more memory available, execution on the CPU is not usually as fast as GPU so the system may choose memory usage accordingly, e.g., greater memory consuming algorithms that trade-off processing speed for more memory. However, a situation may arise where there is no choice and only a CPU node 270 is allocated or only a GPU 280 is allocated where the visualization code executes alongside a simulation. The visualization code initially has no knowledge of the allocated compute resource 410 until it starts running (executing) on the resource. Once executing, the visualization code issues queries to determine the compute resource 410 on which it is executing, e.g., CPU, GPU, as well as available memory/storage resources of the HSS 500.

FIG. 5 is a schematic block diagram of the hierarchical storage system (HSS) 500. In an embodiment, the HSS 500 may be embodied as an abstraction of the cloud file system 360 and database 370 of the cloud-based framework 300. Illustratively, the cloud file system 360 may be a network file system that interoperates with storage devices organized as storage tiers of a cloud service provider (CSP). The CSP storage tiers may be arranged as storage hierarchy levels of the HSS 500 that include the storage devices such as arrays of hard disk drives (HDDs 510) and solid-state drives (SSDs) 520, as well as random access memory devices (e.g., organized as memory 530) and portions of memory (e.g., organized as caches 540) of compute resources 410, such as CPU nodes 270 and GPUs 280. Data movement is significant (consequential) in the cloud-based framework 300, particularly when data items are large and loading of the data from a lowest level (CSP storage tier) of file system storage is relatively slow. Data may be placed at various CSP storage tiers of the HSS 500 depending on speed, capacity, and status of the data. For example, data “at rest” may be encrypted and persistently resident on HDDs 510 of the HSS 500, whereas data “in use” may be stored on SSDs 520 (e.g., organized as secondary cache and located on a same physical rack as compute resources 410), memory 530 (e.g., organized as main memory 124) of a compute resource 410 (such as a CPU node 270) and one or more layers of caches 540 (e.g., organized as primary cache and located on the compute resources 410) for fast data access.

In an embodiment, the visualization code executing on the allocated compute resource 410 may decide how to access the HSS 500 to acquire the data it needs. For example, the visualization code may need to read a simulation file or need a pointer to access data resident in memory 530 of HSS 500. When executing on a GPU 280, the visualization code may issue system calls through a GPU pipeline to the memory 530 (e.g., of HSS 500 on a CPU node 280) or to the cloud file system 360 of the HSS 500. In a post-processing use case having an interactive session between a user and the cloud-based framework 300, the user may specify certain filters, e.g., computer code configured to reduce a number of data elements according to a criteria or pattern. If the dataset is small enough, the framework 300 may dynamically choose to use GPU 280 (because it is typically faster than CPU). If the data set is too large and the performance cost of streaming data to/from GPU (e.g., memory of the GPU) is prohibitive, the framework may choose to use a CPU node 270. Notably no decision is made a priori as to where to run the visualization code (beforehand); instead, the decision is dynamically based on where the data resides so that the visualization code is placed proximate to the data. In this manner, the visualization code does not make such a decision beforehand; rather the cloud-based framework 300 makes the decision of allocating a compute resource for running the code according to proximity criteria for access to data by the code.

One or more components of the scientific visualization system 400 may gather intelligence for use with resource prediction algorithms that are executed to determine resources to allocate for certain execution environments, as well as to determine how well (i.e., efficient) the algorithms perform based on empirical behavior and feed that intelligence back to the cloud-based framework 300. For example, consider a use case of the scientific visualization system 400 that involves users that connect to the cloud-based framework 300 and load visualization projects onto compute resources 410 for sessions that are instantiated by the framework. By gathering intelligence (e.g., information) about various types of visualization projects and their consumed processing resources, as well as the amount of memory consumed for these projects, the scientific visualization system 400 may enable the cloud-based framework 300 to make predictions for resource allocation needed for future instantiations. The framework and system are then able to determine the amount of HSS storage (e.g., memory 530) to allocate to an instantiated session despite the framework being unaware of what visualization processing the user wants to perform. Note that intelligence gathering is not limited to resource allocation, but also applies to automatic visualizations generated by the ML component 800 of the scientific visualization system 400 based on information gathered from monitoring of user activities.

In an embodiment, the scientific visualization system 400 supports multiple execution environments including transient simulations (i.e., simulations that evolve over time) and steady-state simulations (i.e., simulations that converge at a single point in time) with substantially large datasets. Visualization codes (algorithms) are not generally time-based except for transient simulation flows, such as a time-dependent computation performed for visualization by placement of a mass-less particle in air and observation of its flow throughout the simulation. Typically, visualization codes operate on simulation data written as a checkpoint and the sequence of time is used to assemble a larger visualization that proceeds steadily through time. Support for the transient and steady-state execution environments requires flexibility to handle constraints of a cloud-based computing environment having diverse (heterogeneous) and dynamically changing virtualized resource requirements, e.g., memory, speed, hardware, and rendering constraints.

To that end, a “portable performance” feature of the scientific visualization system 400 allows for execution on different computational resources by providing an abstraction layer (software library) application programming interface (API) that enables compiling of the visualization code (e.g., filters) for execution across the multiple (different) compute resources 410 (CPU nodes 270 or GPU 280) of the VDC 200, i.e., portable performance provides a “single code base, multiple use case” solution via the abstraction layer library. Illustratively, the visualization code is written in a manner that is flexible enough to meet resource constraints (available compute/memory) within the dynamically changing, resource-bounded (constrained) environment according to various strategies, e.g., use as little memory as possible or execute as fast as possible. The portable performance (“portability”) feature may further extend to visualization rendering such that the same visualization rendering code may be employed for a client 950 lacking processing resource capabilities (e.g., a “thin client” needing server-side rendering) or a client 950 having sufficient processing capabilities (e.g., a “thick client” capable of client-side rendering). For example, the scientific visualization system 400 provides server-side rendering of visualization images, e.g., generation of the visualization images on the server (VDC) of the cloud-based framework 300 and video streaming to a client 950. If the client computer has sufficient compute (GPU) capacity, the system 400 streams visualization data (e.g., mesh geometry and scalar data) to the client. The portability feature of the system 400 may thus be embodied as a plurality of targeted abstraction layer libraries (i.e., hardware specific implementations of the abstraction layer libraries) that enables compiling and execution of visualization code on either the server or the client so that placing execution of visual rendering may be negotiated according to client capabilities.

In an embodiment, the components of the scientific visualization system 400 cooperate to perform in-situ or in-transit simulation visualization, along with automatic analysis, where visualization code may be executed (i) on a compute resource 410 sharing memory 530 and computation with a portion of the simulation, (ii) on a separate compute resource 410 (i.e., not sharing execution with the simulation), or (iii) as a post-process (after completion of the simulation). Moreover, the scientific visualization system 400 may be configured to consume, synthesize, and organize (i.e., make sense of) large amounts of datasets as an ensemble of simulation results by, e.g., creating visualizations that enable interactive querying based on user-controllable filters. Notably, the user-controlled filters help users manage the volume of simulation results (i.e., size of datasets) through steering the simulation to decimate (i.e., reduce) the datasets to areas of interest for visual comparison and navigate through the reduced (i.e., filtered, decimated) datasets (extracts) within a single user-interactive platform. This latter aspect of the system includes both quantitative filtering (e.g., parameter filter expressions), as well as qualitative visualization for ensemble analysis, such as automatically increasing detail as the viewed simulation results are narrowed or reduced.

In-situ visualization is a mode of visualization processing that may involve tightly coupled processing where visualization code compute tasks (operations) are executed directly on the same compute resources 410 (e.g., GPUs 280) as the simulation while it is running, e.g., the visualization code may be “piggy-backed” (placed) along with the simulation for scheduling and execution on a separate compute resource. However, there may be constraints that require running the visualization code on different compute resources 410 (e.g., CPU nodes 270) and with limited memory 530. Accordingly, the in-transit mode may involve moving data to a different (separate) resource for visualization processing where the separate compute resource receives the data over a network segment (e.g., network segment 123, 140, or 160 for intra-node, inter-node, or inter-VDC data transfer) and processes the data locally on that resource. The separate compute resource 410 may receive simulation data, e.g., in memory 530, before it is saved in the file system 360 of the HSS 500 and the scientific visualization system 400 may perform “automatic analysis” or machine learning to determine a course of action on the data while resident in memory 530. The scientific visualization system 400 determines and automatically selects an efficient mode to implement in each situation, e.g., the system manages distribution of the compute tasks among compute nodes 120 to obtain the resources needed to provide the compute capability depending on user demand for the degree of refinement desired by a user.

FIG. 6 is a schematic block diagram of an exemplary embodiment 600 of the scientific visualization system 400. Illustratively, the visualization components of the scientific visualization system 400 cooperate to place or move processing (e.g., calculations) of the visualization code (e.g., manifested as compute tasks) to locations of the compute resources 410 in proximity to where data (i.e., intermediate simulation results relevant for visualization) resides, e.g., in GPU memory for execution on a GPU 280 alongside simulations (including mesh generation), in CPU memory on a CPU node 270, or on a post-processing resource (allocated GPU or CPU). Illustratively, the DPSL component 700 maintains location information for the compute tasks so that tasks operating on or using the same information may be placed in proximity for high bandwidth, low latency access to that information (e.g., shared access to data in a memory of a GPU). For example, the GPU 280 may execute simulations 310 along with visualization code (vis code 610) to generate checkpoints 620 (full simulation snapshots persisted at points in time) and extracts 630 of predefined visualizations (e.g., slices and contours into portions of the simulation dataset that are essentially sub-sets of the checkpoints) for storage on the HSS 500. A client 950 (user) may provide user actions 615, e.g., one or more visualization parameters and user defined visualizations, embodied as compute tasks directed to the simulations from a user interface (UI) 960 to the ML component 800. As used herein, a compute task includes predetermined post-processing analysis actions either from a user template or ML suggestion. Essentially, the compute task includes “data preparation” tasks for visualization that run in tandem with (or immediately after) the simulation. Those tasks prepare the data for the post-processing resources 910 that stream (forward) the data to the (thin/thick) client 950. The user actions 615 of the compute tasks may be stored on the database 370 and retrieved by the ML component 800 to automatically generate anticipated (i.e., user expected based on past behavior) “automatic visualizations” 640 that are then scheduled for “batch processing” by a compute resource (e.g., CPU resource 650) via the DPSL component 700. As used herein, batch processing denotes non-interactive visualization and analysis.

The CPU resource 650 processes the automatic visualization 640 in connection with the checkpoints 620 and extracts 630 to generate reduced representations 660 (reduced checkpoints) and images 670 that may be provided to the post-processing resources 910 for interactive exploration by the client 950 (user). In an embodiment, the reduced representations 660 and images 670 may reflect, e.g., decimated meshes and compressions to enable interactive exploration of (i) full simulation data, (ii) extracts, or (iii) reduced images at the post-processing resources 910 with a user (client 950). The CPU resource 650 computes the reduced representations 660 and images 670 while or after the simulation executes. The reduced representations 660 and/or images 670, along with full simulation data, may be forwarded to a user on the client 950 as images either automatically generated or in response to user commands, and may be explored (processed and analyzed) interactively by the user in accordance with either client-side (thick client) or server-side (thin client) rendering. Note that the UI vis code 610 on the client 950 is illustratively a compute task that is either generated by a user or automatically generated by the visualization code.

In an embodiment, one or more components (e.g., the DPSL 700) of the scientific visualization system 400 operate cooperatively with the predictive scheduler 330 of the cloud-based framework 300 to allocate and schedule the compute resources 410 (e.g., GPUs 280 and CPU nodes 270) to perform requested computations of the visualization code (manifested by compute tasks) on simulations (as well as mesh generation) either in-situ (e.g., executing on GPUs 280 or CPU nodes 270) or as separate kernels (e.g., executing on GPUs 280). For example, mesh generation may import a computer aided design (CAD) description of a surface and meshing parameters to generate a mesh that is written as a file 355 to the cloud file system 360. The visualization code may read the mesh file and display a mesh on a display screen of a UI 960 of a client 950. A user may request a slice of the mesh which is executed as a compute task (visualization code) to generate a slice for display. Once the mesh and/or slice are generated, a computation may be performed on the mesh/slice and served for display.

### Data Processing Scheduling Layer (DPSL)

FIG. 7 is a schematic block diagram of the data processing scheduling layer (DPSL) component 700 of the scientific visualization system 400. In an embodiment, the DPSL component (hereinafter DPSL 700) is configured to schedule storage of objects (data items) and compute tasks 710 specific for visualization that process the data items to extract data from simulations either in-situ or after the simulation execution and cooperates with the predictive scheduler 330 for the simulation itself. To that end, the 10 DPSL 700 determines the size of the data item, an identifier (ID) of the data item, a HSS location and associated compute resource 410 for storing the data item, and a HSS location at which to send a compute task 710 for execution on the compute resource storing the data item. For example, the DPSL 700 ensures that the data item written by the simulation (data producer) can fit on the HSS storage resource (e.g., memory 530), i.e., the DPSL 700 determines the size of the data item before writing the item to the storage resource of the HSS 500. Requests transmitted to and received by the DPSL 700 illustratively include one or more of the size of the data item and its ID, as well as the storage location (on the compute resource) of the HSS 500 and the compute task 710 that operates on the data item.

In an embodiment, the DPSL 700 may be embodied as an independent scheduler or a super-set scheduler disposed over the predictive scheduler 330 associated with simulation execution. For example, the DPSL 700 may be organized as a caching layer of the predictive scheduler 330 of the cloud-based framework 300. Similar to the predictive scheduler, the DPSL 700 may be an adjunct scheduling layer that maintains the locations of compute and storage resources allocated to a user's application. That is, the DPSL 700 provides a layer of data scheduling that is separate and additional to the predictive scheduler functions. Illustratively, the DPSL 700 is essentially an intermediary configured to redirect compute tasks 710 (e.g., visualization actions or operations) to the HSS 500. That is, the DPSL 700 redirects a compute task 710 to a compute resource 410 where the data item that is needed for the task resides, whereas the predictive scheduler 330 determines what resources are available and provisions those resources as needed.

In an embodiment, the DPSL 700 includes scheduling logic 750 configured to maintain state information related to where data items are stored for precise compute task scheduling, predictively analyze when a data item will become available based on empirical (past) or dynamic (current) performance feedback through the simulation, and schedule callbacks that are invoked as the data items become available, i.e., the visualization code registers callbacks for dynamic scheduling as the data items of the simulation become available. Illustratively, the scheduling logic 750 of DPSL 700 considers a length of time needed to execute a compute task 710 in conjunction with gathered intelligence (e.g., statistics) that create an empirical model to facilitate scheduling of the compute task 710. That is, the DPSL scheduling logic 750 may be configured to perform data collection to gather information about input data size, output data size, and the time needed to perform operations of the compute tasks 710. The scientific visualization system 400 may then “learn” from the gathered information as visualization workflow progresses. For example, assume it takes 10 secs for data of a particular size to be output from the simulation as a computed time step to memory 530 for volatile storage on the HSS 500 as a data item on a node and then to the cloud file system 360 for persistent storage as a checkpoint 620 on a persistent storage device of HSS 500. If there are no available compute nodes 120 to store a next computed time step output, DPSL 700 may skip visualization processing by a compute task 710 on the next data item and allow the data item to be persistently stored as a next checkpoint 620. Subsequently, DPSL 700 may surface the skipped checkpoint 620 and schedule the compute tasks 710 when the resources are available. Alternatively, DPSL 700 can halt simulation execution until the resources become available.

An aspect of the scientific visualization system 400 involves executing the visualization code proximate to where the data resides, e.g., sending compute tasks 710 to the compute resources 410 at which the data resides. In contrast, prior systems typically place or move data to where the compute resources reside to achieve locality. The compute tasks 710 may be scheduled according to user or template demand and prepare the data for transmission through the post-processing resources 910 to the client 950. A simulation executor or data producer 720 (e.g., simulation 310 executing on a GPU 280) writes the data to an HSS location on a compute resource 410, wherein the data is needed for the compute task 710. The DPSL 700 schedules the compute task 710 to process the data, e.g., in memory 530 of the compute resource 410, before the data is written to the cloud file system 360. This represents a processing efficiency aspect of the scientific visualization system 400. The DPSL 700 has knowledge of where the data for the compute task 710 resides, e.g., the compute steps of the task are inserted with a GPU kernel (or next to the GPU kernel in its own kernel) or on the same CPU nodes 270 where the data resides.

For example, the data producer 720 (e.g., the simulation 310) executing on a compute resource (e.g., GPU 280) writes data as files 355 of a checkpoint 620 or full snapshot (e.g., data item S0) of the simulation to the HSS 500. The data producer 720 may issue and forward a system call to DPSL 700 to write the data to HSS 500. In response, the DPSL 700 determines where to write the data item, e.g., to which level and device of the storage hierarchy. A compute resource 410 (e.g., a CPU node 270) may receive the data item S0 from the DPSL 700 for storage in, e.g., memory 530. The data item may have an associated identifier (ID) written by the simulation executing on the GPU resource 280. A compute task C0 (e.g., code and actions) may be created for a service that requires the data item ID and, as a result, C0 registers with the DPSL 700. The DPSL 700 forwards the compute task C0 to the location of the data item (i.e., the memory 530 of the CPU node 270) so that the CPU node 270 at which the data resides executes the code of the compute task 710. If the data item S0 is not resident in the memory 530, the DPSL 700 retrieves (loads) the data item by surfacing it through the storage hierarchy levels to the memory 530 of the CPU node 270. The compute task code thereafter executes on the CPU node 270 using the data item S0 resident in the memory 530. If a subsequent compute task C2 is created (e.g., by a user) for a service that requires the data item ID after the compute task C0 is processed and the data item S0 is stored, e.g., on a persistent storage device such as HDD 510, for another simulation, HSS 500 loads the data item S0 into a memory 530 of a compute resource 410 and DPSL 700 schedules C2 to that compute resource.

Assume now that a data item (e.g., a slice S3) of a simulation is computed by the GPU 280 and saved in a memory location of the HSS 500. A compute task C1 may be created to process the slice and feed the processed slice S3 for storage on the database 370 of the HSS 500. A UI 960 connects to the cloud-based framework 300 (e.g., DPSL 700 of the scientific visualization system 400) and a browser application (browser 965) of the UI 960 requests the slice S3 to interactively display to a user in the browser 965. The UI 960 sends a request to the DPSL 700, which locates and accesses the slice S3, and streams the data (e.g., via the post-processing resources 910) to the browser 965. Note that the streaming output to the browser 965 is dependent on the architecture of the client computer (e.g., a thin or thick client). For a thin client (insufficient processing capabilities), the output may be as simple as a single image of the slice, whereas for a thick client (sufficient processing capabilities) the output may be as complicated as geometries of a decimated mesh that is visualized using, e.g., a web graphics library (such as WebGL) in the user's (client's) browser. That is, for a thick client, geometry parameters of the decimated mesh may be streamed to the client's browser 965 for visualization rendering at the client 950, whereas for a thin client, a data server (e.g., GPU 280) of the cloud-based framework 300 renders the images and streams the image (as a video stream) to the client's browser 965.

In an embodiment, the DPSL 700 is configured to perform load balancing among all the compute and storage resources and, to that end, is responsible for instantiating the resources and monitoring their usage so that it can schedule new work efficiently. The DPSL 700 may schedule a data item (e.g., a checkpoint 620) written by a data producer 720 (e.g., simulation 310) executing on a compute resource 410 (e.g., GPU 280) for storage on a resource (e.g., memory 530) of the GPU 280. A storage request for the data item is forwarded to the DPSL 700, which is responsible for routing the request to an appropriate resource to store the data item. A compute task 710 that requires the data item is forwarded to DPSL 700, which routes the task to the compute resource 410 for execution that stores the data item. For example, assume compute tasks C0-C1 require work to be performed on the same data item S0. DPSL 700 may predict the amount of work needed for the compute tasks and the amount of time the memory resource storing 50 will be consumed by the work.

Predictive scheduling by the DPSL 700 is an aspect of the scientific visualization system 400 that is based on implementation of semi-empirical models (including the use of machine learning). If the models predict that the storage resource will be busy for an extended period of time, the scheduling logic 750 of DPSL 700 considers the prediction in view of the fundamental scheduling criterion to move the compute task 710 to where the data resides and may save the data item S0 as a checkpoint 620. Note that the saving of a checkpoint 620 is itself a compute task 710 that includes processing the data item, compressing it and sending the compressed data to the cloud file system 360 for persistent storage on HSS 500. A subsequent compute task C2 may execute later in time and the DPSL 700 may retrieve (surface) the data item from a persistent storage layer of the HSS 500 into memory 530 of a local compute node 120 for execution. That is, if the storage resource is busy, the DPSL 700 may save the data item and schedule one or more compute tasks 710 (that are dependent on the data item) for execution at a later time. The intelligence (knowledge) may be incorporated into the DPSL scheduling logic 750 as part of a constraint analysis that the DPSL 700 performs to decide where to place data (loads) on the storage resources of HSS 500.

### Artificial Intelligence/Machine Learning (AI/ML)

FIG. 8 is a schematic block diagram of the artificial intelligence/machine learning (AI/ML or, more generally, ML) component 800 of the scientific visualization system 400. In an embodiment, the ML component 800 (hereinafter ML 800) may be configured to generate automatic visualizations for the simulations based on a variety of input data 810, such as expected user behavior, nature of the simulations and user actions. A feature of the ML 800 includes “automatic processing” that creates automatic visualizations 640 to assist users (e.g., citizen users) to explore and find aspects of data they might not typically find before interacting with a simulation (e.g., a simulation file). Illustratively, the ML 800 may determine and generate automatic visualizations 640 for simulations based on user actions, class of problem addressed, types of geometries and categories that are gathered and stored in the database 370 and subsequently processed by the ML 800. The automatic visualizations 640 generated by the ML 800 include automatic images (such as an automatic report) and/or suggestions for additional exploration by a user using the post-processing resources 910. Illustratively, the generated automatic visualizations 640 have a good chance for convergence and provide reasonable views for a visualization service that may be provided at a reasonable cloud-based service offering SaaS rate.

In an embodiment, the ML 800 provides a machine learning function (e.g., a neural network) that is configured by training data 820 to analyze the input data 810 and provide suggestions for simulation configurations used to drive the simulations as well as generate the visualizations. The machine learning function may be implemented using a neural network (or any type of similar AI algorithmic technology, such as a support vector machine) to analyze the input data 810 (such as user actions) and provide suggestions for simulation configurations stored, e.g., in a configuration file. The user actions may be graph-based and provided to the ML 800 to render an image (view) for automatic visualizations 640. Aspects of the scientific visualization system 400 described herein include providing the user actions to drive a current simulation as well as to drive subsequent simulations using, e.g., back channeling from a user exploring the data.

In an embodiment, the training data 820 may include simulation settings 822, mesh metadata 824 and user interaction data 826 that may be represented as user analysis information embodied as a set of visualization filters and filter parameters used to create automatic visualizations 640 (e.g., 2D graphs or 3D views). The simulation settings 822 may be user provided settings that define the simulation (e.g., materials, turbulence models, steady state versus transient, moving grid, temperatures and heat fluxes, frequency ranges) associated with different types of physics. Mesh metadata 824 may include information describing a mesh, such as a number of cells, control volumes, surfaces, fields and field ranges, shape and other derived statistics about the mesh data. User interaction data 826 may include a class of data input to the ML 800 that represents user interactions such as common camera angles, probe locations (user defined special locations of interest) and any other data derived from user input. A probe point enables clicking (via an input device) and probing of a value at a specific point in space. Such probing enables determination of probe locations, preferred camera angles (for most common camera angles) and other special locations of interest to users based on filters they employ.

In an embodiment, the ML 800 processes the training data 820 to determine what the user is attempting (i.e., intended nature of the simulation) based on user simulation settings 812 (parameters) and mesh metadata 814 provided as user input data 810 (user actions) as well historical user patterns captured in the training data. The ML 800, in turn, processes the input data 810 in accordance with the training data 820 to produce (as output) automated visualizations 640. For example, if a user “clips off” a substantial part of a volume to only focus on a small subset of the volume, the ML 800 may use that user action information to predict actions for rendering the automatic visualizations 640. This aspect of the scientific visualization system 400 applies to any other data derived from user input data 810. Essentially, the ML component ingests user interaction data/input data to develop a corpus of training data 820 for ML 800 to produce the automated visualizations 640. In one or more embodiments, the automated visualizations 640 may be presented in the form of an analysis task graph 850 having a base point 852 (e.g., representing the full simulation dataset) connected to intermediate points 854 (e.g., representing sub-sets of the dataset such as a slice) arranged in a tree structure. Illustratively, the ML 800 is configured to produce the analysis task graph 850 as output (e.g., a set of suggested analysis operations for a simulation result) to the CPU resource 650, which may be used by the DPSL 700 to schedule visualization tasks to execute the actions according to the task graph.

In an embodiment, the analysis task graph 850 provides a scheduling schema wherein requested operations may be processed as the simulation executes to, e.g., periodically write-out checkpoints 620 (snapshots) of the simulation at predefined, discrete advancements in time, i.e., time steps (e.g., every 100 cycles). Each write operation is illustratively a compute task 710 that is assigned an object or data item identifier (ID). For example, the user may request display of every 100 time steps of the simulation written as checkpoints 620. In an embodiment, the user request may be manifested as a compute task 710 of the task graph 850 as “save time step 100 (snapshot in time) (ID0)”. The user may request a next task that specifies “slice the field at a (some) point” having assigned ID1. A subsequent, child task may be “save the (results of the) slice having assigned ID3.” Each of these tasks is a point 852, 854 on the task graph 850, wherein some of the tasks assume a parent-child relationship. For example, compute task ID2 may be “contour the slice” and ID4 may be “save the contour.” Note the tasks enumerated in the task graph 850 are determined a priori (beforehand) in response to a user request and scheduling logic 750 of the DPSL 700 (in cooperation with the predictive scheduler 330) allocates the resources needed to store and compute the tasks identified by IDs.

In an embodiment, the ML 800 is configured to perform intelligence gathering for instant, real-time analysis of data. An instant analysis feature of the scientific visualization system 400 enables the ML 800 to auto-generate images and representations for users as simulations run and before interaction with the data. That is, a user does not have to immediately interact with a full simulation dataset but may instead examine one or more smaller images. Illustratively, the system has knowledge of the simulations that are running (via the solver settings), the visualizations that are being processed (via values input by the user) and the general analysis being performed for such simulations and visualizations. The ML 800 of the system 400 may provide suggestions to users about what they should look for in their data.

In an embodiment, the inputs and outputs of the ML 800 may be specific to the simulation processed by the scientific visualization system 400. That is, the level of intelligence gathering by the system 400 may include an understanding of the type and class of problem addressed by the simulation and the visualizations desired. For example, the mesh metadata 824 may include discrete geometry parameters, as well as computer-aided design (CAD) files and other classifiers for ingestion into the ML 800 to train and inform the ML 800. Note that the mesh metadata input 814 may include a mesh file instead of a CAD file; however, if a CAD file is provided by a user, the cloud-based framework 300 may generate a mesh, and both the mesh metadata and CAD metadata may be ingested into the ML 800.

One approach for intelligence gathering is to “mine” gathered data to determine, e.g., simulation settings 812 of users, which provide “hints” as to what they are trying to simulate. For example, the mined data may reveal simulation settings that indicate turbulence or steady-state simulation. These simulation settings 812 (parameters) enable insight to the scientific visualization system 400 as to what users typically simulate with such parameters, such that the system may automatically generate visualizations for next users based on common simulations in the technological space. For instance, users generating a type of simulation (as determined by the parameters) may desire slice planes as visualization views. When the users explore data, the scientific visualization system 400 of the cloud-based framework 300 records their actions, e.g., the filters and values applied. The system may surmise that, for analysis specific simulations, users typically provide such settings/parameters and request such visualizations. That is, for a wind tunnel simulation, wind is spread over an aircraft and standard operations are performed by a user. Such intelligence gathering and automatic visualization generation via a visualization API tool provides suggested visualizations based on use cases (types of simulations).

In an embodiment, non-machine learning (non-ML) methods may be employed, such as auto-camera placement, to automatically create images from best angles and create slices at interesting areas of data based on historical data or features in the data that are identified and interesting to users. A non-ML based deployment may involve a vendor/manufacturer (e.g., of airplanes) that, for each simulation, desires a predetermined number of slice planes of a number of contour surfaces and custom points-of-view, e.g., organized as a template. This deployment is in contrast to the ML 800 deployment that is trained to recognize an airplane being analyzed based on the simulation settings 812, 822 and mesh (and/or geometry, CAD) metadata 814, 824 inputs and, in response, produces automated visualizations 640 for processing and analysis. A template embodiment (described further herein) provides a user with exactly what they desire for exploration and analysis, whereas the ML embodiment provides suggested automated visualizations 640 based on inputs. Note that the ML embodiment relates to intelligence gathering based on user activities across a variety of workloads. The gathered intelligence may then be used to train the ML 800 to provide a citizen user with suggested initial automatic visualizations 640. This aspect of the scientific visualization system 400 may be embodied as a “visualization assistant” configured to suggest visualizations for a user that may be subsequently “tailored” by, e.g., adding or removing details, etc. The final visualization may then be applied to a template for use on a next similar simulation.

### Dynamically Negotiating Client-Server Visual Rendering

In an embodiment, a dynamically negotiating client-server visual rendering component 900 of the scientific visualization system 400 provides interactive and negotiating communication between one or more clients 950 (e.g., endpoints displaying/rendering visualization information) and the post-processing resources 910 of the system 400. Illustratively, interactive negotiation between the post-processing resources 910 and clients 950 operates as an independent service to determine the resource capacity and capability of the clients 950 such as a “thin client” needing server-side rendering vs a “thick client” capable of client-side rendering, to handle various types of streams and data sent over the streams, as well as impact on resource scheduling for the server-side rendering so as to apportion (deploy) visualization rendering between the client and the system. The scientific visualization system 400 may then provide a data streaming service depending on user demand, templates, parameters, session configuration and setup with client (users), each having different visualization requirements. In response to the negotiating communication, the post-processing resources 910 streams an appropriate amount of data and detail to the clients 950, some of which may have “weak” (i.e., bandwidth constrained) communication interconnects or links (and thus receive reduced versions of streaming data) and some having large bandwidth links capable of receiving enhanced feeds or streams (greater detailed simulation data). If a client-side rendering deployment exceeds its resource capabilities (e.g., frame rate dropping below a threshold), seamless failover or fallback to server-side rendering or other error handling may be provided.

In an embodiment, the scientific visualization system 400 supports client-side programs that interact over networks with the server (e.g., VDC 200) in the cloud-based framework 300 to fetch data needed to fulfill user requests. Existing visualization systems that provide visualization rendering are mostly post-processing desktop applications (not cloud solutions) that are incapable of providing the entire end-to-end service offerings that include both simulation execution and visualization rendering. These existing systems are constrained by client-side code that requires constant updates and delivery of new versions to clients. In contrast, the visualization system service described herein is a cloud solution that is instantly updated to latest versions available in the cloud for the latest visualization capabilities. In addition, the visualizations may be quite large and difficult to download. The scientific visualization system 400 overcomes these disadvantages by executing the visualization code where the data resides in the cloud and sending only data that a user can successfully process (e.g., in its browser 695) over the network connection from the cloud-based server.

Referring again to FIG. 6, the scientific visualization system illustrates client-side and server-side visualization rendering. In a server-side rendering embodiment, all data analysis, filter computation, and rendering occurs on the post-processing resources 910 (e.g., post-processing server 930), and one or more video streams 914 of simulation results and findings is sent to the UI 960 of the client 950. Illustratively, a dedicated compute resource (GPU) may be allocated to operate as the post-processing server 930 of the scientific visualization system to render a video stream from visualization code (vis code 610) executing on the GPU and encode the video stream 914 forwarded to the client 950. Server-side rendering may be employed for a thin client deployment where the allocated resource (compute and memory capacity) is appropriate for the size of the data, which is then read (loaded) from the HSS 500 to the allocated resource. The HSS 500 and allocated resource then provide the video streaming capacity 914 (including video compression) to the client 950.

In a client-side rendering embodiment, all visualization rendering occurs on the compute resource (e.g., GPU) of the client 950. Accordingly, there is no dedicated GPU resource allocated at the post-processing resources 910 of the scientific visualization system 400 and one or more compute resources (e.g., CPU node) of the cloud-based framework 300 may operate as a remote data/analysis server 920. Client-side rendering may be employed for a thick client deployment. The data/analysis server 920 receives visualization data (including geometry parameters) from the HSS 500 and computes visualization filters 915 that are sent over geometry streams 916 to the client 950 for rendering. In one or more embodiments, the visualization filters 915 (along with filter parameters) may be embodied as user filtering actions provided by the client and executed by the data/analysis server 910 to create visualizations, such as two dimensional (2D) or three dimensional (3D) graphs.

FIG. 9 is a schematic block diagram of the dynamically negotiating client-server visual rendering component 900 of the scientific visualization system 400. In an exemplary embodiment, the post-processing resources 910 may deploy two sets of resources for client interaction: server-side rendering resources and client-side rendering resources. The server-side rendering resources include the post-process server 930 embodied as one or more dedicated GPUs 280 for collaboration support. A presenter (UI 960) of the client 950 may forward commands (embodied as user control actions 912) to the post-process server 930 (server-side rendering) to control (i.e., filter) data. The dedicated GPU 280 processes the commands and returns one or more video streams 914 to at least one collaborator/viewer (UI 960). In another embodiment, multiple video streams 914 from the same GPU 280 can be sent to both the presenter (in full control of the analysis) and one or more remote collaborators/viewers. For an illustrative collaboration environment, the scientific visualization system 400 may support multiple video streams 914 to multiple collaborators as, e.g., a simulcast of a video screen.

Client-side rendering includes one or more geometry (and solutions) streams 916 forwarded from the post-processing resources 910 to UI 960 where vis code 610, e.g., a graphics library, executes on a compute resource (GPU) at the client 950 for interaction with the data/analysis server 920 of the post-processing resources 910. In an embodiment, a CPU node 270 of the data/analysis server 920 may stream the data (e.g., geometry stream 916) to the graphics library (e.g., WebGL) running inside a web browser 965 of the client 950 for visualization rendering (client-side rendering). The geometry stream 916 illustratively includes mesh geometry and scalar data. The geometry stream 916 is also progressive, i.e., several increasingly complex level-of-detail (LoD) meshes may be contained in the stream. The streamed visualization data may assume the form of interactive automated reports or parameters for mesh processing. In response to receiving the geometry stream 916, the client 950 may perform visualization rendering processing (e.g., rendering of geometric shapes such as triangles, and application of color maps). The streamed visualization data may include volumetric data as well as reduced representations 660 that enable, e.g., interactive slicing in the client's browser 965. The client 950 may request full computation from the server-side (post-process server) to, e.g., provide interactive pre-views of data from a particular slice plane.

A challenge associated with dynamically negotiating client-server rendering 900 of the scientific visualization system 400 is that resources (e.g., memory) available on a client 950 (e.g., customer laptop connected to a network 150 for access to the cloud-based framework 300) are opaque to the system 400 and may not be sufficient or adequate to provide the rendering service requested by the client 950. As a result, client-side rendering may fail due to, e.g., resource capacity strain, necessitating a “seamless” fallback/failover to server-side rendering. To that end, the scientific visualization system 400 is configured to maintain the client connection long enough to avoid interruption of the user experience while falling back to server-side resources needed to provide the service. The system 400 monitors performance of visualization rendering on the client side to determine when such performance is inadequate so that it may automatically switch to server-side rendering.

FIG. 10 is a schematic block diagram illustrating a client-side rendering fallback workflow 1000 of the scientific visualization system 400. The fallback workflow 1000 may involve a thick client exceeding the resource (memory 1010) capacity on the client computer (client 950). For example, a LoD deployment with geometry streamed to a client's browser 965 may fail because the geometry stream 916 may exceed the memory capacity of the client. In an embodiment, the deployment may include LoD representations 1020 (e.g., visualization extracts) for each geometric object stored in the client's memory 1010. The visualization extracts produced by the scientific visualization system 400 may be quite large, particularly when presenting and displaying many extracts at the same time to a client (user) in a report template, which consumes more resources than in a typical use case. To maintain user experience, the scientific visualization system 400 may invoke the fallback workflow 1000 that includes (1) a recovery action to evict (delete) finer LoD visualization representations (e.g., views B and C) stored in memory 1010 in lieu of maintaining storage of coarser representations (e.g., view A) so as to free-up the memory and maintain interactivity while switching to a different processing mode (server-side rendering) or provisioning new resources. A backup compute resource (e.g., backup GPU 280A) may be reserved on the data/analysis server 920 of the post-processing resources 910. If freeing memory does not enable recovery, the fallback workflow 1000 may (2) switch to a backup video stream 1030 from the backup GPU 280A to maintain interactivity while (3) a server-side rendering instance 1050 is invoked (instantiated) and started. The backup GPU 280A may then (4) transfer the data to the server-side rendering instance 1050, which includes a fallback GPU 280B configured to take over (assume) performance of server-side rendering. The server-side rendering instance 1050 then (5) video streams 914 to the client. The client-side rendering fallback workflow 1000 may thus be provided for a deployment having an additional backup GPU 280A provisioned on the data/analysis server 920 of the post-processing resources 910 for immediate fallback when transitioning to a fallback GPU 280B for server-side rendering.

FIG. 11 is a schematic block diagram of client-side rendering fallback 1100 of the scientific visualization system 400. In an alternate embodiment, data/analysis server 920A,B of the post-processing resources 910 utilizes similar resources for client-side and server-side rendering to perform filtering, as well as generating geometry. In addition, a dedicated render server 1110 (e.g., a plurality of GPUs) is responsible for visualization rendering and associated tasks including video streaming. This alternative embodiment simplifies the fallback procedure 1000 by allocating a GPU from the dedicated render server 1110 having sufficient memory (e.g., video RAM) to accommodate the video streams 914 instead of falling back to a backup GPU 280A. Illustratively, the scientific visualization system 400 has the capability to run filters on both CPU and GPU; accordingly, the data/analysis server may alternatively be embodied as a CPU node configured for, e.g., multi-threading computations. Thus, in one or more embodiments, the render server 1110 may include CPU nodes and GPU. Notably, there is no allocation of GPU for client-side rendering deployment since this deployment uses the client's GPU. This alternative deployment has an architectural organization that reduces overall cost of resources.

Illustratively, the entire visualization (library) code may be run on the GPU in accordance with the portability feature of the scientific visualization system 400, but use of the CPU node is cheaper and easier to allocate, and more suited to accommodate the large data sizes, i.e., the CPU memory footprint is much larger than GPU memory. Also, the computation speed of GPU is not needed for streaming geometry parameters which involves preparing geometry to reduce rendering costs by, e.g., eliminating internal faces leaving only the external part of the dataset and stream the reduced geometry to the client CPU. The scientific visualization system 400 provides non-interactive visualization and analysis processing (i.e., batch processing) where the render server 1110 includes GPUs 280 or, alternatively, CPU nodes 270 configured to execute filters and information for rendering using graphics libraries that do not need GPUs to perform such rendering. For such non-interactive batch processing, the render server 1110 may be configured with one or more arrays of GPUs and CPUs, and batch jobs may be provided to the render server for processing. For in-transit processing, visualization compute tasks 710 operate on simulation data being written by a GPU 280. These compute tasks 710 are scheduled (by DPSL 700) for execution on a separate compute resource 410 that is also responsible for writing data to HSS 500. Where a batch process is launched after the simulation execution completes and the simulation data has been persistently saved on the HSS 500, the DPSL 700 may retrieve (“surface”) the data into memory 530 of a compute resource 410 (such as a CPU node 270) and map the compute tasks 710 to the memory 530 for operation on the data, i.e., at the location where the data resides.

In batch processing mode, visualization parameters may be provided, e.g., in a configuration file, before simulation execution commences (non-interactively). For example, the simulation may be instructed to compute a data item (slice) and save the computed data item, possibly without saving the entire simulation dataset. A time step (e.g., output as a checkpoint 620) of the simulation data may not be persisted in the file system 360 and only be resident in memory 530. The DPSL 700 may move a compute task 710 to the compute resource 410 at which the simulation dataset resides in memory 530 for operation on (and persistent storage of) only the slice (sub-set) of the dataset, i.e., compute and only save the slice or compute the slice and save the entire checkpoint 620 including the slice. Unlike batch processing mode where the simulation runs and completes at a later time, a post-processing mode may facilitate interactivity with a user that may request visualization views (e.g., slice planes) for the simulation. The post-processing mode may be modified such that a simulation 310 (including a checkpoint and time steps) may not be persistently saved and user requests for views (slice planes) may be made a priori, i.e., the simulation execution extracts and renders the slice planes. Thus, the scientific visualization system 400 contemplates many processing modes extending from fully interactive to fully batched, as well as modes therebetween, including modes where compute tasks 710 are computed directly inside the simulation (data producer) executing on the compute resource 410 (GPU).

In an embodiment, the scientific visualization system 400 may provide a plurality of techniques or tools (i.e., a toolbox) from which users can choose to best suit their applications, e.g., an aerodynamics simulation (e.g., airplane) may require different tools from those needed for a hydrodynamics simulation (e.g., fire suppression). In the case of ensemble analysis, the toolbox may provide multiple, portable performance layers directed to where code executes and where rendering is performed, e.g., to optimize for mesh types. The toolbox may also generate (i) a series of images of interest, (ii) interactive explorations with a user's browser where, for image databases, a user can drag an image to rotate to another image and simulate an entire piece of data, and (iii) subsequent recoloring of the image. In addition, the toolbox may provide full, but reduced, 3 dimensional (3D) representations of the data used to compare different simulations before a user loads the data and interacts with the scientific visualization system. In essence, the toolbox allows dynamic resolution scaling and data fetching depending on the resolution needed for a visualization area of interest, i.e., only fetch data from that area at the improved resolution. For example, if a user wants to compare multiple representations, the system may invoke a coarsest (least) level of detail, but once the representations are narrowed to a few comparisons, may increase the level of detail to full level comparison so as to examine the actual data. For interactivity, the toolbox feature of the system may be applied to automated reports. The system 400 allows use of different tools from the toolbox to analyze workloads depending on applications, wherein the toolbox may include, e.g., individual analysis methods and flexibility of portable performance layers.

In an embodiment, the scientific visualization system 400 may provide a sophisticated LoD deployment with geometry streamed to a client's browser 965 depending on the client's resource capacity which, in turn, determines a level of interactivity and granularity of data for the user to process/analyze and eventually compare with a full computation dataset. In this context, interactivity may denote, e.g., clicking on a UI display and rotating an image interactively or placing and moving a slice plane and calculating the slice at interactive rates, as well as other denotations depending on demand. Such interactivity requires a system flexible enough to parametrically determine the tasks needed to complete, as well as the configuration needed to compute logic or kernels of the visualization code and interactively solve user requests. Essentially, the visualizations are user specific based on the simulation and requiring a range of capacities to accommodate various user requests. For example, a user may interactively move a data item (e.g., a slice or contour) around a display screen of a UI 960 during a visualization session to perform, e.g., slicing or clipping. The user may also submit a substantial number (thousands) of simulations for running in batch mode (i.e., non-interactive and not requiring immediate processing). Yet, the user may desire visualizations that display the data item (or object) in various points of views, such as slice planes at various locations of the object. Batch visualization may produce many images for subsequent (later) non-interactive exploration and analysis. Note that an in-situ deployment involves creation of the visualization images while the simulation 310 (calculation) runs, such that memory 530 and compute resources 410 are utilized for both the physical simulation and specifics of the requested visualization.

In an embodiment, visualization rendering may involve generation of automated reports, where many users may desire a standard template based on workflows. For example, a user may desire standard visualizations (e.g., images) that are generated with slice planes applied across the images. Such a template is tedious to configure and setup manually. An aspect of the scientific visualization system 400 is directed to native support of an automated report feature that includes the ability to organize and display all of the visualizations with relevant metadata in a document/report, e.g., a PDF file with all of the images, plots, texts, etc. Assume a user desires to perform a design of experiments (DoE) that requires running a substantial amount (thousands) of simulations and sorting through the generated simulation data. The scientific visualization system 400 may create a standard analysis plan or template that can be applied to all of the simulations. The template is initially created in the UI 960 and allows the user to specify the organization and content of an automated report, a priori. As used herein, a priori denotes visualization actions defined by the user before simulations have run, wherein the actions may occur in-situ or as a batch process. Thereafter, the infrastructure (e.g., components) of the scientific visualization system 400 is invoked to execute the template. Examples of template features include basic statistics about fields (such as minimum or maximum pressure during a simulation run), two-dimensional (2D) plots (such as a time history of variables over time for each simulation, generation of a fixed, static image, and LoD extracts). As for the latter, assume a slice or contour mesh is created (e.g., that consumes a substantial amount of storage) and decimated (compressed, made smaller) in several layers. A highest layer may be a full dataset followed by lower layers that decimate (reduce) the dataset.

In an embodiment, the scientific visualization system 400 may be configured to consume, synthesize, and organize (i.e., make sense of) large amounts of datasets as an ensemble of simulation results by creating visualizations. For example, to enable examination of a plurality of simulations, the scientific visualization system 400 may create an automated report web page that displays the simulation results. The report may be sent to the client 950 and displayed as, e.g., linked graphs of data items such that a user can click and drag the graphs to observe a same point-of-view for each data item.

The system enables changing of applied color maps, comparing of values at particular points, and sub-selecting of a minimum subset of the graphs to provide a finer level of detail for comparison using visualization that enable interactive querying based on user-controllable filters. Notably, the user-controlled filters help users manage the volume of simulation results through steering the simulation to decimate (i.e., reduce) the datasets to areas of interest for visual comparison and navigate through the reduced (i.e., filtered, decimated) datasets (extracts) within a single user-interactive platform. For example, the size and quality of the ensemble of simulation results visualized on the client may be continuously adjusted based on the client's capabilities for interactive viewing and querying of the datasets. This aspect of the system includes both quantitative filtering (e.g., parameter filter expressions), as well as qualitative visualization for ensemble analysis, such as automatically increasing detail as the viewed simulation results are narrowed or reduced.

FIG. 12 is a diagram illustrating an interactive hierarchical DoE exploration feature 1200 of the scientific visualization system. The interactive hierarchical DoE exploration feature 1200 enables interactive exploration of substantially large amounts of data. For example, an iso-surface (dataset) may be initially displayed, e.g., on a report web page, as a 3×4 matrix of visualizations displayed as thumbnails. The feature 1200 may then be invoked to decimate (reduce) the dataset to a sub-set for analysis, e.g., instead of a 3×4 visualization display, a user may be presented with a 2×2 or 1×2 display of datasets. Another example may be to decimate a large number of datasets resulting from a large number (1000s) of simulations to a reduced subset (10-20) with which the user can efficiently interact, and ultimately launching two full sessions where the remaining subsets can be explored in a same manner.

FIG. 13 is a diagram of a linked time slider 1300 of the scientific visualization system 400. In an embodiment, the linked time slider 1300 may be implemented in UI 960 to enable visualizations of transient simulations that “move through time” and allow filtering of data by a user. Typically, only a single time step of the simulation may be displayed and analyzed because the dataset is large. In accordance with a feature of the system, the linked time slider 1300 may be employed to move through the different time steps to explore the movement of the simulation. Because of the breadth of the data, such analysis and display are difficult to make interactive. Therefore, the scientific visualization system 400 creates extracts that allow exploration and analysis of, e.g., simulations that evolve through and over time. The post processing resources 910 process (e.g., post-process) every time step that is available in a compressed form for loading onto the client's machine for fast display and analysis.

In an embodiment, the visualization rendering features of the scientific visualization system 400 are API driven through the UI 960 as to how the displayed visualizations are presented to the user such as, e.g., a template that provides an easy graphical way to present, store and recall feature requests. The template allows the user to select an arrangement of desired features, e.g., a 1-day plot, 2-day plot and an image, such as a slice, contour, and associated parameters. This arrangement of features translates into one or more compute tasks and/or API calls that are generated as the simulation runs and as they traverse the HSS storage levels. The template features may be stored as a template file, parsed, and executed via API calls or compute tasks. Illustratively, the components (e.g., ML 800, DPSL 700, and dynamically negotiating client-server rendering 900) of the scientific visualization system 400 cooperate to enable template report generation and presentation of ensemble analysis. For example, the ML 800 may enable report template generation such that the system may suggest automatic visualizations of template report styles based on the type of simulation being executed as specified by input parameters. This feature substantially reduces the time to provide useful visualizations that are displayed in a compelling and informative manner.

In an embodiment, the report template provides information, such as parameters, that are applied to simulation computation results (e.g., via kernels) to produce template elements that are thereafter graphically rendered, arranged, and presented on a UI display screen to a user. Examples of the template elements include 2D plots, images, statistical summaries, and interactive 3D views. These template elements describe outputs of the scientific visualization system and how they are presented to a user. Illustratively, the report template parameters may be loaded and scheduled on the kernels for computation of the template elements, such as visualizations (images or 3D views) and/or computational data (statistical summaries or 2D plots) that are arranged (e.g., by a layout arrangement) and presented to a user.

For example, the scientific visualization system 400 may perform visualization actions to produce an output (e.g., an intersection curve) of a 2D plot that displays, e.g., a slice of an airplane wing and plot of values of the airplane. The system gathers and computes the data (as described herein) and the report template is directed to the presentation of the computations in a manner that can be consumed by a user when viewing the results of many (100s or 1000s) simulations. Illustratively, the report template contains parametric information (parameters) used to inform the system about the data to extract from the simulation data computed by the simulation execution (run). Once a report template is created describing output elements for each simulation run, the template can be applied “en masse” to all simulation runs under a design of experiments (DoE). That is, the template may be used again for other simulation runs to specify the data to be extracted from the runs. The extracted data (extracts) may then be arranged and presented to the user. Applying the template to a simulation initiates automated workflows to generate the data in batch mode by, e.g., utilizing all of the components of the scientific visualization system.

In an embodiment, the layout arrangement of the scientific visualization system arranges the report template elements in a manner that can be consumed efficiently by a user. Each template element may be configured by, e.g., specifying information requested by a user and how that information is to be presented to the user. Components of the scientific visualization system may provide configuration assistance to the layout arrangement by filtering the information (e.g., many simulations and resulting datasets) in response to a user request to quickly reduce a large amount of simulation data to a smaller and manageable amount of interest to a user using a visualization query language. Once the datasets are filtered to a reasonable size, meaningful and effective comparisons may be performed between the filtered datasets of an ensemble exploration data stream. That is, the stream may include an arrangement of individual dataset results that are selectable for comparison (e.g., coarser to finer LoD) using the visualization query language.

In one or more embodiments, the visualization query language may be a domain specific language (e.g., based on a syntax of a conventional language such as Python) that allows a user to express queries to filter or parse data extracted from simulation datasets (extracts 630) before applying template elements to the extracts and forwarding them to the layout arrangement. That is, the visualization query language may be employed by a user to specify requests for presentation and display of specific visualizations (e.g., that require calculation of derived fields to extract data) using a filtering stage prior to visualization of extracted data. For example, the user may employ the visualization query language to request only simulation data that has a maximum pressure of less than a specified value. Once the data is extracted from the simulation datasets, the query language may be used to interactively apply a desired template element to the resulting datasets.

Given the computational cost of visualizations, the ability to create expressions that focus visualization analysis to exactly what a user desires (without incurring additional cost), such as through the use of the scientific visualization system 400 having computational steering capabilities, may be advantageous and beneficial. For example, assume a simulation involves a projectile approaching a wall. In response to detecting an impact, the scientific visualization system may be steered to trigger computation of a visualization depicting the resulting impact. In an embodiment, the scientific visualization system 400 provides such computational steering using a trigger that may employ the visualization query language, a derived field expression or possibly a mixture of queries and analysis. An example of a trigger may be a cost saving measure, e.g., if a maximum pressure exceeds a physical value, immediately halt (stop) the simulation execution.

### Operation

Assume a user initiates a simulation (e.g., a golf ball simulation) that executes on the server (VDC 200) of the cloud-based framework 300 and inputs operational parameters (organized and formed as a compute task) directed to visualization of the simulated golf ball. For example, the user may want to simulate the drag, lift, and flow field behind the golf ball as it is struck and spins through space. As time advances, the orientation of the golf ball may change. When analyzing the flow behind the golf ball, the user may want to observe where the flow separates and movement of the separation through time. Here, the golf ball is at the center of the mesh (i.e., a volumetric mesh) that extends throughout the displayed space. The user may want to slice the golf ball (e.g., in half) and view or plot certain physical properties (e.g., the velocity magnitude) behind the ball. The user connects to the cloud-based (SaaS) framework 300 to load a visualization project (visualization code) onto a dedicated compute resource 410 for a session instantiated by the framework. In response to a user request for certain visualization parameters for interacting with the simulation, the scientific visualization system 400 determines where to run (compute) the visualization code using data needed to perform the visualization computations, e.g., CPU node 270, GPU 280, or post-processing resources 910. The system 400 may dynamically determine (on-the-fly) where to run the code depending on the parameters and/or where the data resides (CPU or GPU memory, or both).

In an embodiment, the visualization computations may be complicated functions such as parametric equations computed to display a data item, such as a slice plane. If a certain value is exceeded, a histogram and simulation data may be computed. The visualization computations may extract the data item from the simulation data, compute the extracted data item, and use the computed extracted data item for the automatic visualizations 640 as part of a visualization work kernel scheduled as a compute task 710. Here, the visualization kernel may operate (work) on the simulation data to perform a user request for visualization, as opposed to work performed in the simulation itself. For example, a script may be developed from a scripting language with conditionals to enable execution of the visualization compute task during the simulation. The script may be configured to drive fetching and computing of data from the simulation. The trigger for DPSL 700 (e.g., to schedule a compute task 710 for ML 800) is user specified and adaptive to the simulation (e.g., “if X happens, do Y”) or (“reaction to current data”).

In an embodiment, the resources needed for the simulation are predetermined and mapped to work (compute tasks/IDs) scheduled by DPSL 700. Parametric equations and data needed from the simulation are assigned tasks/IDs, which may have dependencies for, e.g., time steps or portions of the volumetric mesh. The DPSL scheduling logic 750 maintains state (i.e., knowledge) of simulation execution flow in the compute resource 410 (e.g., GPU pipeline) and storage locations of resulting data output from the compute resource. According to an aspect of the scientific visualization system, the DPSL 700 utilizes the state to schedule (place) compute tasks 710 into compute resources 410 (CPU/GPU) at which the data resides (memory) for execution and subsequent extraction of computed data. To that end, DPSL 700 may receive input of scheduled simulation code and simulation data layout (e.g., on GPU pipelines) to enable identification of the compute node 120 at which data resides and the time at which the data is resident on the node. This, in turn, enables DPSL 700 to schedule its tasks with the simulation execution and allows extraction and/or operation on the data resident in the memory 530 of the node 120 before persistent storage of the data in HSS 500. Notably, the simulation execution generally has no knowledge of the visualization code, but the visualization code execution does have knowledge of the simulation. The simulation execution writes out data items (such as slices or contours of a volumetric mesh) with object IDs and DPSL 700 determines where the data items reside (on which nodes) and when the data items are available (e.g., in memory) on the nodes 120. DPSL 700 may then schedule visualization compute tasks 710 directed to (and dependent on) the data item IDs. As noted, the simulation execution illustratively may write out checkpoints 620 periodically (e.g., every 100 secs). DPSL 700 can thus preemptively schedule resources (e.g., memory, compute, etc.) knowing that there are tasks to be performed on the checkpoints. However, DPSL 700 can also schedule tasks on demand.

For example and referring again to FIG. 7, the golf ball simulation may be a data producer 720 that writes a time step (50) having an ID0 via, e.g., a storage request to the DPSL 700 to store 50 on the HSS 500. DPSL 700 determines that there are compute tasks 710 that need ID0 and, in response, writes 50 to storage/memory of a compute node 120 (e.g., forming a storage layer of HSS 500) before scheduling the compute tasks 710 for execution on the compute node 120 to enable operation on 50. Assume the computed data, e.g., a slice of the volumetric mesh, needed by the compute tasks 710 (as extracted from the simulation) are subsequently saved to HSS 500. DPSL 700 may determine that the necessary resources (e.g., memory 530) are currently constrained and that the computation events specified by the compute tasks 710 may be delayed. Accordingly, DPSL 700 writes (stores) the slice to a persistent storage device layer (e.g., SSD 520 or HDD 510) of the cloud file system 360 and subsequently retrieves (surfaces) the slice (data item) for computation when the necessary resources are available. Thus, the DPSL scheduling logic 750 considers (i) resource availability and (ii) statically reacts to available resources and data location for current computation of data or (iii) predictively reacts to when the resources and data will be available for subsequent computation of the data.

Typically, DPSL 700 does not “drive” execution of the simulation, i.e., instead of the DPSL driving (scheduling) changes to the simulation, the simulation runs on its own schedule and the DPSL 700 (and compute tasks 710) adapt to the simulation execution. Yet, there may be visualization system deployments that include feedback to allow the DPSL 700 and compute tasks 710 to drive changes to the simulation. For example, a user may request running of many (1000s) simulations for a DoE. The user may further request predefined visualization compute tasks 710 (computations) that may be enumerated in a template or configuration file of user interaction data and scheduled on compute resources 410 reserved by DPSL 700 during a negotiation exchange between the user and the scientific visualization system 400. The user interaction data may be fed into the ML 800 (as input data 810) and examined to determine appropriate automatic visualizations to generate and output. The compute tasks 710 (e.g., embodied as an analysis task graph 850) are then scheduled on the reserved compute resources 410 for computation and generation of the visualizations. Although typical ML execution is via non-interactive batch processing, the scientific visualization system 400 may be adaptive to consider current values (e.g., statistical summaries) of data that exist in the simulation to inform the automatic visualization generation. For instance, a histogram of velocity may be used as an “on-the-fly” trigger to dynamically adapt the visualization display.

While there have been shown and described illustrative embodiments of a scientific visualization system including a plurality of components configured to provide visualization of filtered results of simulations executing on virtualized resources of a cloud-based VDC computing environment, it is to be understood that various other adaptations and modifications may be made within the spirit and scope of the embodiments herein. For example, embodiments have been shown and described herein with relation to the simulation executing on its own schedule and the components of the scientific visualization system adapting to the simulation execution. However, the embodiments in their broader sense are not so limited, and may, in fact, allow one or more of the system components (e.g., DPSL) to control the simulation execution, e.g., retard or pause execution to extract data, through the use of computational steering. An example of a trigger for computation steering may involve recognition of degraded numerical values that result in inaccurate output, such as when a pressure value exceeds a reasonable threshold. Accordingly, the simulation may diverge and execution may be halted to conserve resources.

Switching physical models for simulations based on dynamic parametric data analysis may be another example that involves a visualization (script) kernel used as a computational steering trigger, i.e., instead of a simulation steering script. The trigger may be used to configure visualization parameters, such as a contour value, to drive the simulation. Since visualization of simulation results are a primary modality of examination of the simulation as it runs and completes, computational steering may further drive the simulation results into areas of visual interest for users. Although examination of the simulation in this context is more exploratory or reactive, such examination may also be used for debugging to halt/stop inaccurate or faulty simulation and/or mesh execution. Essentially, triggers used as simulation (solver) stopping criteria may prove advantageous by allowing users to express conditions of the physics that control or steer (drive) the simulation. To that end, the scientific visualization system allows a user to input their own code that runs with the simulation to impart domain knowledge as, e.g., computational steering.

The foregoing description has been directed to specific embodiments. It will be apparent, however, that other variations and modifications may be made to the described embodiments, with the attainment of some or all of their advantages. For instance, it is expressly contemplated that the components and/or elements described herein can be implemented as software encoded on a tangible (non-transitory) computer-readable medium (e.g., disks and/or electronic memory) having program instructions executing on a computer, hardware, firmware, or a combination thereof. Accordingly, this description is to be taken only by way of example and not to otherwise limit the scope of the embodiments herein. Therefore, it is the object of the appended claims to cover all such variations and modifications as come within the true spirit and scope of the embodiments herein.

What is claimed is:

1. A non-transitory computer readable medium including program instructions for execution on hardware resources of a virtual data center (VDC) and client device, the program instructions configured to:
allocate the hardware resources of the VDC for execution of scientific visualization of a physical simulation, wherein the scientific visualization is configured to execute on different types of the hardware resources according to a hardware independent application programming interface;
place tasks of the scientific visualization for execution on the hardware resources in proximity to data of intermediate results from execution of the physical simulation at the VDC; 11 render images using the scientific visualization tasks based on datasets from the execution of the physical simulation; and
one of (i) send the rendered images for display at the client device or (ii) send physical simulation data for rendering and display at the client device.

2. The non-transitory computer readable medium of claim 1, wherein the program instructions for execution on the hardware resources include program instructions further configured to apply user-controlled filters to manage a size of the datasets.

3. The non-transitory computer readable medium of claim 2, wherein the user-controlled filters steer the execution of the physical simulation to manage the size of the datasets.

4. The non-transitory computer readable medium of claim 2, wherein the user-controlled filters reduce the datasets of the physical simulation to areas of interest for visual comparison and navigation through the reduced datasets at the client device.

5. The non-transitory computer readable medium of claim 2, wherein the scientific visualization tasks are configured to synthesize and organize the datasets as an ensemble of simulation results that enable interactive viewing and querying at the client device based on the user-controllable filters.

6. The non-transitory computer readable medium of claim 5, wherein a size and quality of the ensemble of simulation results visualized on the client device is continuously adjusted based on capabilities of the client device for interactive viewing and querying of the datasets.

7. The non-transitory computer readable medium of claim 2, wherein the user-controllable filters include parametric filter expressions.

8. The non-transitory computer readable medium of claim 1, wherein the program instructions for execution on the hardware resources include program instructions further configured to trade-off memory consumption of the scientific visualization tasks for processing speed when the tasks are placed at processing resources of the hardware resources of the VDC.

9. The non-transitory computer readable medium of claim 8 wherein the processing resources are graphics processing units.

10. The non-transitory computer readable medium of claim 1, wherein the scientific visualization tasks execute in parallel with the execution of the physical simulation.

11. A method comprising:
allocating hardware resources of a virtual data center (VDC) for execution of scientific visualization of a physical simulation, wherein the scientific visualization is configured to execute on different types of the hardware resources according to a hardware independent application programming interface (API);
placing tasks of the scientific visualization for execution on the hardware resources in proximity to data of intermediate results from execution of the physical simulation at the VDC;
rendering images using the scientific visualization tasks based on datasets from the execution of physical simulation; and
and one of (i) sending the rendered images for display at the client device or (ii) sending physical simulation data for rendering and display at the client device.

12. The method of claim 11 further comprising applying user-controlled filters to manage a size of the datasets.

13. The method of claim 12, wherein the user-controlled filters steer the execution of the physical simulation to manage the size of the datasets.

14. The method of claim 12, wherein the user-controlled filters reduce the datasets of the physical simulation to areas of interest for visual comparison and navigation through the reduced datasets at the client device.

15. The method of claim 12, wherein the scientific visualization tasks are configured to synthesize and organize the datasets as an ensemble of simulation results that enable interactive viewing and querying at the client device based on the user-controllable filters.

16. The method of claim 15, wherein qualitative visualization for analysis of the ensemble of simulation results is automatically increased in detail as the viewed simulation results are narrowed at the client device.

17. The method of claim 12, wherein the user-controllable filters include parametric filter expressions.

18. The method of claim 11, further comprising trading-off memory consumption of the scientific visualization tasks for processing speed when the tasks are placed at specialized processing resources of the hardware resources of the VDC.

19. The method of claim 11, wherein the scientific visualization tasks execute in parallel with the execution of the physical simulation.

20. A system comprising:
one or more compute nodes of a virtual data center (VDC) having hardware resources configured to execute a scientific visualization system configured for interactive visualization of simulation results, the scientific visualization system configured to:
allocate hardware resources of the VDC for execution of scientific visualization of a physical simulation, wherein the scientific visualization is configured to execute on different types of the hardware resources according to a hardware independent application programming interface;
place tasks of the scientific visualization for execution on the hardware resources in proximity to data of intermediate results from execution of the physical simulation at the VDC;
render images using the scientific visualization tasks based on datasets from the execution of the physical simulation; and
one of (i) send the rendered images for display at the client device or (ii) send physical simulation data for rendering and display at the client device.
